(19) United States
(12) Patent Application Publication
(10) Pub. No.: US 2026/0090465 A1
(43) Pub. Date: Mar. 26, 2026

(54) RADIO-FREQUENCY (RF) INTEGRATED CIRCUITS (ICs) EMPLOYING MULTIPLE COUPLED DIES FOR FACILITATING ELECTRICAL ISOLATION OF RF DEVICES, AND RELATED FABRICATION METHODS

(71) Applicant: QUALCOMM Incorporated, San Diego, CA (US)

(72) Inventors: Abhijeet Paul, San Diego, CA (US); Mishel Matloubian, San Diego, CA (US); Periannan Chidambaram, San Diego, CA (US)

(21) Appl. No.: 18/892,671

(22) Filed: Sep. 23, 2024

(51) Int. Cl. H01L 25/065; H01L 25/00

(52) U.S. Cl. CPC H10W 90/00

(57) ABSTRACT

Radio-frequency (RF) integrated circuits (ICs) employing multiple coupled dies to facilitate electrical isolation of RF devices, and related methods of fabrication are disclosed. To provide enhanced electrical isolation of RF semiconductor devices in the IC from other devices without being required to include a specialized higher resistivity layer in a substrate of a bottom die, the IC also includes a second, top die. The top die includes second, RF semiconductor devices configured to emit RF energy that are desired to be electrically isolated from first semiconductor devices in the bottom die. The top die is coupled to the bottom die in a top-to-top coupling configuration to provide signal routing paths between the bottom and top dies, which also locates the second RF semiconductor devices in the top die and the first semiconductor devices in the bottom die apart from each other in their respective dies for enhanced electrical isolation.

### TECHNICAL FIELD

The field of the disclosure relates to a radio-frequency (RF) integrated circuit (IC) die that includes RF semiconductor devices used to form RF circuits, wherein the IC die can be included in an IC package.

### BACKGROUND

Modern smart phones and other portable devices have extended the use of different wireless links with a variety of technologies in different radio frequency bands. For example, fifth generation (5G) cellular networks, commonly referred to as 5G NR include frequencies in the range of 24.25 to 86 Gigahertz (GHz), with the lower 19.25 GHz (24.25-43.5 GHz) more likely to be used for mobile devices. To support the integration of one or more radio-frequency (RF) transceivers in a device, the RF transceivers are integrated in RF integrated circuit (IC) (RFIC) transceiver chips in an RFIC package. A conventional RFIC package includes one or more ICs provided in the form of IC chips, a power management IC (PMIC), and passive electrical components (e.g., inductors, capacitors, etc.). The IC chips are mounted to a substrate support structure as part of the RFIC package. The support structure may include one or more metallization structures to provide chip-to-chip and external signal interfaces to the IC chips. The RFIC package may also include an integrated antenna module that is electrically coupled through a metallization structure(s) to the IC transceiver chip to receive electrical signals that are radiated as electro-magnetic (EM) signals.

ICs are provided in the form of an IC die that includes RF semiconductor devices (“RF devices”) (e.g., transistors employed in a RF signal power amplifier, RF switch, RF filter) and other non-RF semiconductor devices (non-RF devices) (mixing circuits, logic circuits, signal generators, etc.). These semiconductor devices are formed in a semiconductor layer disposed on a silicon substrate in wafer form as part of a front-end-of-line (FEOL) fabrication process and then diced into individual dies. For example, the wafer may be a silicon-on-insulator (SOI) wafer than employs a thin buried insulator layer (BIL) (e.g., a buried oxide (BOX) layer) to provide electrical isolation between the semiconductor layer and the semiconductor devices formed therein and a silicon substrate. A back-end-of-line (BEOL) process is performed to form an interconnect structure on the opposite side of the substrate that contains metal layers with metal interconnects formed therein and coupled to the semiconductor devices formed in the semiconductor layer to provide signal routing paths to the devices. RF devices often require a high degree of RF isolation to achieve a desired linear response needed for operation. However, even with the presence of the BIL layer, electric fields generated by fluctuations in the signals in these RF devices can still cause charge to build up in the substrate and activate charge carriers in the substrate due to intrinsic capacitance between the RF devices and the substrate. This can create unintended RF signal paths between RF devices through the activated substrate leading to inter RF device interference. Thus, to reduce or avoid this RF interference, conventional ICs are formed on a specialized wafer with a specialized substrate that includes an additional high resistivity layer with lower electron mobility (e.g., a trap rich layer) between the semiconductor layer and the substrate to provide improved isolation between RF devices and the substrate. This specialized substrate increases the thickness of the substrate and the overall IC die, and comes at a higher cost because of specialized fabrication steps used to create the high resistivity layer.

### SUMMARY OF THE DISCLOSURE

Aspects disclosed herein include radio-frequency (RF) integrated circuits (ICs) employing multiple coupled dies to facilitate electrical isolation of RF devices. Related methods of fabrication are also disclosed. In exemplary aspects, the IC includes a first, bottom die that includes first semiconductor devices formed in a first semiconductor layer coupled to a first substrate. The first substrate may be a silicon-on-insulator (SOI) substrate to provide enhanced electrical isolation between the first semiconductor devices, which may include RF and non-RF semiconductor devices. The bottom die includes a first interconnect structure coupled to the first semiconductor layer to provide signal routing paths to the first semiconductor devices in the first semiconductor layer. It is desired to include RF semiconductor devices that emit RF energy in the IC. However, electric fields generated by fluctuations in signals in such RF semiconductor devices can cause charge to build up in the substrate and create electrical paths between the RF semiconductor devices and other semiconductor devices present in the same semiconductor layer unless a specialized substrate is employed with an additional higher resistivity layer (e.g., trap rich layer) at increased cost and complexity. In exemplary aspects, to provide additional, enhanced electrical isolation of RF semiconductor devices in the IC from other devices in the IC without being required to include a specialized higher resistivity layer in the substrate of the bottom die, the IC includes a second, top die. The top die includes second, RF semiconductor devices that are configured to emit RF energy and thus are desired to be highly electrically isolated from the first semiconductor devices in the bottom die, which may be non-RF semiconductor devices that are not configured to emit RF signals. The second, semiconductor RF devices in the top die are formed in a second semiconductor layer coupled to a second substrate, which may also be an SOI substrate. To provide enhanced electrical isolation between the second, RF semiconductor devices and the first semiconductor devices, the top die is flipped with its second interconnect structure coupled (e.g., bonded) to the first interconnect structure of the bottom die in a top-to-top coupling configuration to provide signal routing paths between the first and second interconnect structures of the bottom and top dies, which also locates the second RF semiconductor devices in the top die and the first semiconductor devices in the bottom die apart from each other in their respective dies for enhanced electrical isolation.

This provides enhanced electrical isolation between the second, RF semiconductor devices in the top die and first semiconductor devices in the bottom die. The semiconductor devices in the IC can be partitioned between the bottom and top die depending on the electrical isolation desired or needed between such semiconductor devices. Thus, the electrical isolation provided by this bottom and top die arrangement in the IC can avoid the requirement of a substrate in the bottom and/or top die including an additional higher resistivity layer (e.g., trap rich layer) to provide enhanced electrical isolation. Also, an increased number of RF semiconductor devices can be provided in the IC without having to necessarily increase the lateral footprint of an IC having a single die to provide sufficient isolation between the RF semiconductor devices. An IC with the coupled bottom and top dies may increase the overall height of the IC, but at the benefit of the ability to include an increased number of devices in the IC while still providing sufficient electrical isolation, as desired.

In other exemplary aspects, the IC can be fabricated in a wafer-to-wafer bonding process for efficient fabrication and so that readily available semiconductor wafers can be used to form the bottom and top dies with readily available wafer processing techniques. In this regard, a first, bottom wafer can be provided in which the first semiconductor devices are formed in a first semiconductor layer therein and the first interconnect structure is then formed on the first semiconductor layer and then diced into a plurality of the bottom dies. Before the bottom wafer is diced, a second, top wafer can be provided in which second, RF semiconductor devices are formed in a second semiconductor layer and the second interconnect structure is then formed on the second semiconductor layer. Metal interconnects on the outer metallization layers of the first and second interconnect structures of the respective bottom and top wafers can then be exposed and the top wafer flipped and its outer metallization layer coupled (e.g., bonded) to the outer metallization layer of the bottom wafer in a top-to-top coupling configuration. Exposed metal interconnects from each outer metallization layer of the bottom and top wafers are coupled (e.g., bonded) to each other as a result of coupling the outer metallization layers of the respective first and second interconnect structures of the bottom and top wafers to form signal routing paths between the bottom and top wafers and thus respective first semiconductor devices and second, RF semiconductor devices. For example, using wafer fabrication processes can support pad-to-pad alignment between the outer metallization layers of the bottom and top wafers to couple the bottom and top wafers together with tighter tolerances thereby allowing tighter pitched metal interconnects (e.g., sub-micron pitch) to be coupled together without having to sacrifice routing density. The combined bottom and top wafers can then be diced to form individual IC packages with bottom and top dies coupled to each other as part of an IC with their respective first and second semiconductor layers and respective first and second substrates isolated from each other on opposite ends of the IC.

In another exemplary aspect, the second substrate of the top die of the IC can be processed to form bump outs (e.g., solder bumps, ball grid array (BGA) interconnects) for external interconnects for the IC to be coupled to another substrate or circuit board as part of an electronic device. In this regard, the second substrate can be removed (e.g., polished or grinded down) and openings formed in the outer metallization layer to form vias in contact with metal interconnects therein, and external interconnects formed in contact with the vias. A dielectric material that is not a semiconductor material for example, can then be disposed adjacent to the outer metallization layer to provide an outer passivation for the top die. This has the advantage of providing additional electrical isolation between the second, RF semiconductor devices in the top die, because the second substrate of semiconductor material from the top wafer used to form the top die is removed and replaced with an alternative second substrate of dielectric material that provides increased electrical isolation.

Note that although the above examples are discussed with regard to the top die including second, RF semiconductor devices that are desired to be electrically isolated from the first semiconductor devices in the bottom die, the reverse can also be provided. That is, the IC can provide that the bottom die includes RF semiconductor devices that are desired to be electrically isolated from other semiconductor devices in the top die.

In this regard, in one exemplary aspect, an IC is provided. The IC comprises a bottom die, comprising: a first substrate extending in a first direction; a first interconnect structure comprising a first side adjacent to the first substrate and a second side opposite of the first side in a second direction orthogonal to the first direction; and a first semiconductor layer adjacent to the second side of the first interconnect structure in the second direction. The first semiconductor layer comprises one or more first semiconductor devices. The IC also comprises a top die, comprising: a second substrate extending in the first direction; a second interconnect structure comprising a third side adjacent to the second substrate and a fourth side opposite of the third side in the second direction; and a second semiconductor layer adjacent to the fourth side of the second interconnect structure in the second direction. The second semiconductor layer comprises one or more radio-frequency (RF) semiconductor devices each configured to emit RF energy. The fourth side of the second interconnect structure of the top die coupled to the second side of the first interconnect structure of the bottom die.

In another exemplary aspect, a method of fabricating an IC package is provided. The method comprises forming a bottom die, comprising: providing a first substrate extending in a first direction; forming a first semiconductor layer adjacent to the first substrate in a second direction orthogonal to the first direction, the first semiconductor layer comprising one or more first semiconductor devices; and forming a first interconnect structure adjacent to the first semiconductor layer in the second direction, such that a first side of the first interconnect structure is adjacent to the first semiconductor layer, the first side opposite a second side of the first interconnect structure in the second direction. The method also comprises forming a top die, comprising: providing a second substrate extending in the first direction; forming a second semiconductor layer adjacent to the second substrate in the second direction, the second semiconductor layer comprising one or more radio-frequency (RF) semiconductor devices each configured to emit RF energy; and forming a second interconnect structure adjacent to the second semiconductor layer in the second direction, such that a third side of the second interconnect structure is adjacent to the second semiconductor layer, the third side opposite a fourth side of the second interconnect structure in the second direction. The method also comprises coupling the fourth side of the second interconnect structure of the top die to the second side of the first interconnect structure of the bottom die.

### BRIEF DESCRIPTION OF THE FIGURES

FIG. 1 is a side view of a radio-frequency (RF) integrated circuit (IC) that includes a die with a semiconductor layer disposed on a silicon-on-insulator (SOI) substrate that includes an additional high resistivity layer between a buried insulator layer (BIL) and a semiconductor substrate to provide additional electrical isolation between RF devices formed in the semiconductor layer;

FIG. 2A is a side view of an exemplary IC that includes a first, bottom die with first, semiconductor devices formed in a first semiconductor layer and a second, top die with second, RF semiconductor devices formed therein formed in a second semiconductor layer, and wherein first and second interconnect structures of the respective bottom and top dies are coupled to each other in a vertical direction in a top-to-top coupling configuration to provide enhanced electrical isolation between second, RF semiconductor devices in the top die, and the first semiconductor devices in the bottom die;

FIG. 2B is a side view of the bottom die in the IC in FIG. 2A;

FIG. 2C is a side view of the top die in the IC in FIG. 2B;

FIGS. 3A-3C are top views of an exemplary IC according to a circuit layout, and its respective circuit sections having RF semiconductor devices and other semiconductor devices provided in a single die.

FIG. 3D is a top view of another exemplary IC that includes a first, bottom die having the second circuit section in FIG. 3B coupled to a separate, bottom die having the first circuit section in FIG. 3C coupled to each other in the second, vertical direction in a top-to-top coupling configuration to provide enhanced electrical isolation between the RF semiconductor devices in the second, top die and other semiconductor devices in the bottom die;

FIGS. 4A-4C are top views of an exemplary IC according to a circuit layout, and its respective circuit sections having RF low noise amplifiers (LNAs) and other semiconductor devices provided in a single die;

FIG. 4D is a top view of another exemplary IC that includes a first, bottom die having the second circuit sections in FIG. 4B coupled to a separate, bottom die having the first circuit section in FIG. 4C coupled to each other in the second, vertical direction in a top-to-top coupling configuration to provide enhanced electrical isolation between the LNA devices in the second, top die and other semiconductor devices in the bottom die;

FIG. 5 is a flowchart illustrating an exemplary fabrication process of fabricating an IC that includes a first, bottom die with first, semiconductor devices formed in a first semiconductor layer and a top die with second, RF semiconductor devices formed therein formed in a second semiconductor layer, and wherein first and second interconnect structures of the respective bottom and top dies are coupled to each other in a vertical direction in a top-to-top coupling configuration to provide enhanced electrical isolation between second, RF semiconductor devices in the top die, and the first semiconductor devices in the bottom die, including, but not limited to, the ICs and dies in FIGS. 2A-2C, 3D and 4D;

FIGS. 6A-6H is a flowchart illustrating another exemplary process of fabricating ICs like, but not limited to, the ICs and dies in FIGS. 2A-2C, 3D and 4D, using a wafer-to-wafer fabrication and bonding process that includes a first, bottom wafer with first, semiconductor devices formed in a first semiconductor layer bonded to a second, top wafer with second, RF semiconductor devices formed in a second semiconductor layer, wherein the bottom and top wafers are bonded to each other in a vertical direction in a top-to-top coupling configuration and then diced into individual ICs;

FIG. 7A-7I are exemplary fabrication stages during fabrication of the IC according to the exemplary fabrication process in FIGS. 6A-6H;

FIG. 8 is a block diagram of an exemplary wireless communications device that includes one or more ICs that each include a first, bottom die with first, semiconductor devices formed in a first semiconductor layer and a second, top die with second, RF semiconductor devices formed therein formed in a second semiconductor layer, and wherein first and second interconnect structures of the respective bottom and top dies are coupled to each other in a vertical direction in a top-to-top coupling configuration to provide enhanced electrical isolation between the second, RF semiconductor devices in the top die, and the first semiconductor devices in the bottom die, including, but not limited to, the ICs and dies in FIGS. 2A-2C, 3D, 4D, and 7D-7I, and that can be fabricated according to a fabrication process, including, but not limited to, the exemplary fabrication processes in FIGS. 5-6H; and

FIG. 9 is a block diagram of an exemplary electronic device in the form of a processor-based system that includes one or more ICs that each include a first, bottom die with first, semiconductor devices formed in a first semiconductor layer and a second, top die with second, RF semiconductor devices formed in a second semiconductor layer, and wherein first and second interconnect structures of the respective bottom and top dies are coupled to each other in a vertical direction in a top-to-top coupling configuration to provide enhanced electrical isolation between the second, RF semiconductor devices in the top die, and the first semiconductor devices in the top die, including, but not limited to, the ICs and dies in FIGS. 2A-2C, 3D, 4D, and 7D-7I, and that can be fabricated according to a fabrication process, including, but not limited to, the exemplary fabrication processes in FIGS. 5-6H.

### DETAILED DESCRIPTION

With reference now to the drawing figures, several exemplary aspects of the present disclosure are described. The word “exemplary” is used herein to mean “serving as an example, instance, or illustration. ” Any aspect described herein as “exemplary” is not necessarily to be construed as preferred or advantageous over other aspects.

Aspects disclosed herein include radio-frequency (RF) integrated circuits (ICs) employing multiple coupled dies to facilitate electrical isolation of RF devices. Related methods of fabrication are also disclosed. In exemplary aspects, the IC includes a first, bottom die that includes first semiconductor devices formed in a first semiconductor layer coupled to a first substrate. The first substrate may be a silicon-on-insulator (SOI) substrate to provide enhanced electrical isolation between the first semiconductor devices, which may include RF and non-RF semiconductor devices. The bottom die includes a first interconnect structure coupled to the first semiconductor layer to provide signal routing paths to the first semiconductor devices in the first semiconductor layer. It is desired to include RF semiconductor devices that emit RF energy in the IC. However, electric fields generated by fluctuations in signals in such RF semiconductor devices can cause charge to build up in the substrate and create electrical paths between the RF semiconductor devices and other semiconductor devices present in the same semiconductor layer unless a specialized substrate is employed with an additional higher resistivity layer (e.g., trap rich layer) at increased cost and complexity. In exemplary aspects, to provide additional, enhanced electrical isolation of RF semiconductor devices in the IC from other devices in the IC without being required to include a specialized higher resistivity layer in the substrate of the bottom die, the IC includes a second, top die. The top die includes second, RF semiconductor devices that are configured to emit RF energy and thus are desired to be highly electrically isolated from the first semiconductor devices in the bottom die, which may be non-RF semiconductor devices that are not configured to emit RF signals. The second, semiconductor RF devices in the top die are formed in a second semiconductor layer coupled to a second substrate, which may also be an SOI substrate. To provide enhanced electrical isolation between the second, RF semiconductor devices and the first semiconductor devices, the top die is flipped with its second interconnect structure coupled (e.g., bonded) to the first interconnect structure of the bottom die in a top-to-top coupling configuration to provide signal routing paths between the first and second interconnect structures of the bottom and top dies, which also locates the second RF semiconductor devices in the top die and the first semiconductor devices in the bottom die apart from each other in their respective dies for enhanced electrical isolation.

This provides enhanced electrical isolation between the second, RF semiconductor devices in the top die and first semiconductor devices in the bottom die. The semiconductor devices in the IC can be partitioned between the bottom and top dies depending on the electrical isolation desired or needed between such semiconductor devices. Thus, the electrical isolation provided by this bottom and top die arrangement in the IC can avoid the requirement of a substrate in the bottom and/or top die including an additional higher resistivity layer (e.g., trap rich layer) to provide enhanced electrical isolation. Also, an increased number of RF semiconductor devices can be provided in the IC without having to necessarily increase the lateral footprint of an IC having a single die to provide sufficient isolation between the RF semiconductor devices. An IC with the coupled bottom and top dies may increase the overall height of the IC, but at the benefit of the ability to include an increased number of devices in the IC while still providing sufficient electrical isolation, as desired.

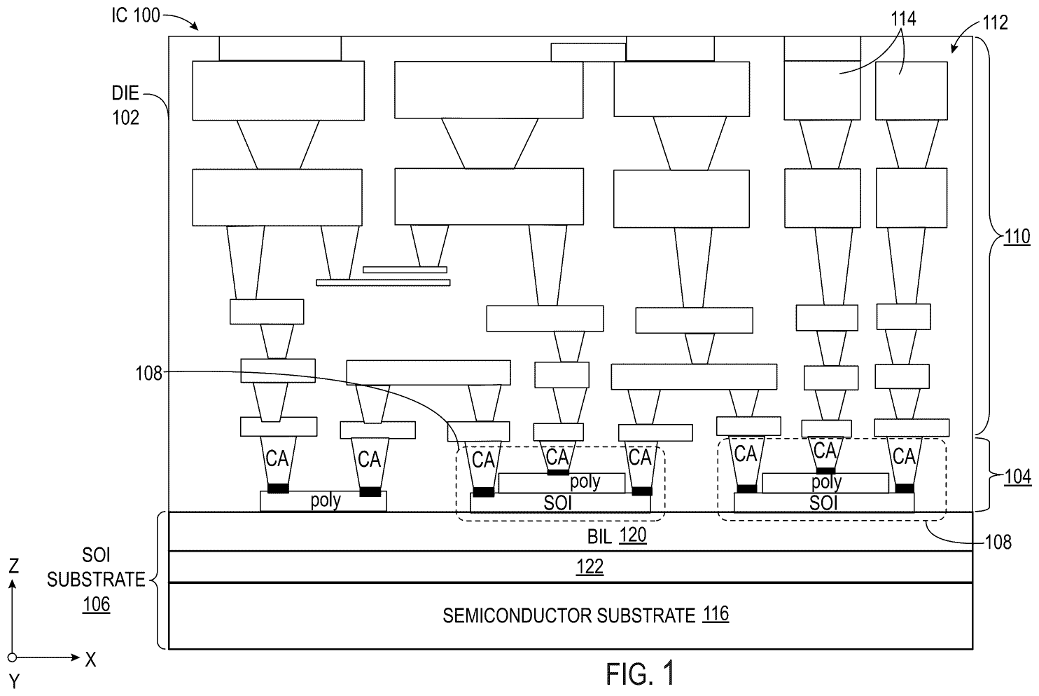

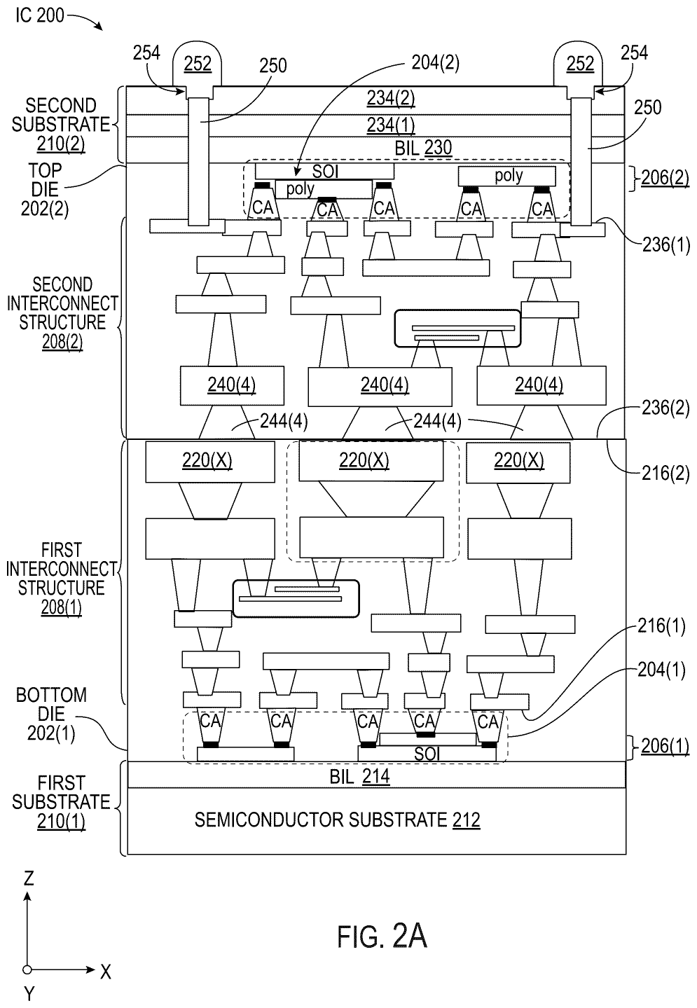

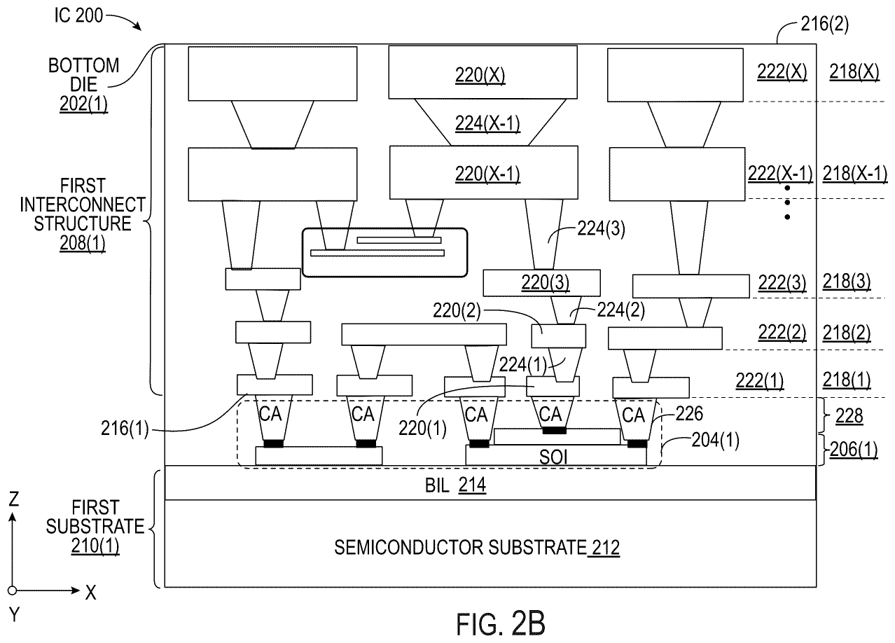

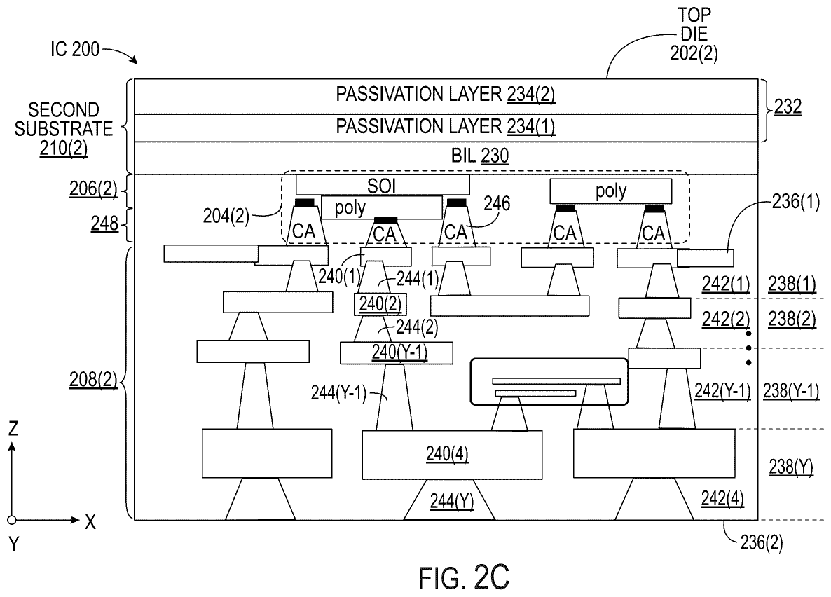

Before discussing examples of ICs that include a bottom die with semiconductor devices and a second, top die with second, RF semiconductor devices coupled together in a top-to-top coupling configuration to provide enhanced electrical isolation between second, RF semiconductor devices in the top die, and the first semiconductor devices in the bottom die starting at FIG. 2A, a conventional IC is described first with regard to FIG. 1.

In this regard, FIG. 1 is a side view of an IC 100 that includes a single die 102 with a semiconductor layer 104 extending in first, horizontal directions (X-axis and Y-axis directions) disposed on a substrate 106 to provide enhanced electrical isolation between RF semiconductor devices 108 (e.g., transistors) that are formed in the semiconductor layer 104. In this example, the RF semiconductor devices 108 are configured to be included in RF circuits (e.g., transceiver, RF filter, RF switch, RF amplifier (e.g., low-noise amplifier (LNA)), etc.), wherein the semiconductor devices 108 are configured to process and emit RF signals for RF signal processing applications. In this regard, the IC 100 can be thought of as an RFIC. The IC 100 includes an interconnect structure 110 that is formed from a back-end-of-line (BEOL) process that includes metallization layers 112 with metal interconnects 114 in each metallization layer 112 coupled to each other according to a circuit pattern to provide signal routing paths to the RF semiconductor devices 108.

To provide support for the IC 100 and the semiconductor layer 104, the IC 100 includes a semiconductor substrate 116 that the semiconductor layer 104 is disposed on in a second, vertical direction (Z-axis direction) orthogonal to the first directions (X-axis and Y-axis directions). The semiconductor substrate 116 is made from a semiconductor material, because the IC 100 was fabricated from a semiconductor wafer in which semiconductor wafer fabrications processes were employed to form the die 102. However, fluctuation in signals in the RF semiconductor devices 108 can cause electric fields 118 to be generated into the semiconductor substrate 116 that can cause charge to build up in the semiconductor substrate 116 and activate charge carriers in the semiconductor substrate 116. Thus, in this IC 100, the substrate 106 also includes a buried insulator layer (BIL) 120 (e.g., a buried oxide (BOX) layer) that the semiconductor layer 104 is disposed on in the second, vertical direction (Z-axis direction). The BIL 120 is designed to provide enhanced electrical isolation between the RF semiconductor devices 108 and the semiconductor substrate 116, however this isolation still may not be sufficient.

In this regard, as shown in FIG. 1, the substrate 106 also includes an additional high resistivity layer 122, that is a trap rich (TR) layer having a higher resistivity than the BIL 120. The high resistivity layer 122 provides even further enhanced electrical isolation between the RF semiconductor devices 108 and the semiconductor substrate 116. The high resistivity layer 122 has lower electron mobility to provide improved isolation between the RF semiconductor devices 108 and the semiconductor substrate 116. However, this causes the substrate 106 to be fabricated or sourced as a specialized substrate for the IC 100, which comes at a higher cost because of specialized fabrication steps used to create the high resistivity layer 122 in the substrate 106. Conventional semiconductor wafers do not include the high resistivity layer 122 in their substrates. Adding the high resistivity layer 122 in the IC 100 can also increase the thickness of the substrate 106 and thus increase the overall height of the IC 100 in the second, vertical direction (Z-axis direction).

To avoid the need to require a substrate of an RF IC that includes RF semiconductor devices to include a high resistivity layer (e.g., a trap rich layer) while also still providing desired electrical isolation of the RF semiconductor devices, an IC 200 in FIGS. 2A-2C is provided. FIG. 2A is a side view of an exemplary IC 200 that includes a first, bottom die 202(1) with first, semiconductor devices 204(1) formed in a first semiconductor layer 206(1), and a second, top die 202(2) with second, RF semiconductor devices 204(2) formed in a second semiconductor layer 206(2). The second, RF semiconductor devices 204(2) are devices (e.g., transistors, diodes, resistors capacitors, inductors) that can be formed in the second semiconductor layer 206(2) and are included in RF circuits configured to process RF signals (e.g., RF transceivers, RF filters, RF switches, RF amplifiers (e.g., low-noise amplifiers (LNAs)), etc.). As shown in FIG. 2A and as will be described in more detail below, first and second interconnect structures 208(1), 208(2) of the respective bottom and top dies 202(1), 202(2) are coupled to each other in the second, vertical direction (Z-axis direction) in a top-to-top coupling configuration to provide enhanced electrical isolation between second, RF semiconductor devices 204(2) in the top die 202(2), and the first semiconductor devices 204(1) in the first, bottom die 202(1).

Thus, the IC 200 in FIG. 2A provides enhanced electrical isolation between the second, RF semiconductor devices 204(2) in the top die 202(2) and the first semiconductor devices 204(1) in the bottom die 202(1). Including the second, RF semiconductor devices 204(2) in a separate top die 202(2) apart from the bottom die 202(1) that includes the first, semiconductor devices 204(1) allows the second, RF semiconductor devices 204(2) to be physically separated from the first, semiconductor devices 204(1) in the bottom die 202(1) in the second, vertical direction (Z-axis direction). The bottom and top dies 202(1), 202(2) are coupled to each other by their respective first and second interconnect structures 208(1), 208(2) being coupled to each other, but in a top-to-top configuration such that the first and second semiconductor layers 206(1), 206(2) of the bottom and top dies 202(1), 202(2) are disposed at opposite ends of the IC 200 adjacent to respective first and second substrates 210(1), 210(2). This avoids or reduces RF energy emitted by the second, RF semiconductor devices 204(2) from interfering with the first semiconductor devices 204(1). For example, the first semiconductor devices 204(1) may be devices (e.g., transistors, diodes, resistors capacitors, inductors) that are included in circuits (e.g., analog and/or digital circuits) that are sensitive to interference from extraneous RF signals for their operation, yet desired to be provided in the same IC 200 as the second, RF semiconductor devices 204(2).

Further, the IC 200 in FIG. 2A allows the first and second, RF semiconductor devices 204(1), 204(2) to be partitioned between the bottom and top dies 202(1), 202(2) depending on the electrical isolation desired or needed between such first and second, RF semiconductor devices 204(1), 204(2). Thus, the electrical isolation provided by this bottom and top die 202(1), 202(2) arrangement in the IC 200 can avoid the requirement of a substrate in the bottom and/or top die 202(1), 202(2) including an additional higher resistivity layer (e.g., trap rich layer) to provide enhanced electrical isolation. Also, the enhanced electrical isolation provided by partitioning the first and second, RF semiconductor devices 204(1), 204(2) in their respective bottom and top dies 202(1), 202(2) may allow an increased number of RF semiconductor devices to be provided in the IC 200 without having to necessarily increase the lateral footprint of the IC 200 if it were to have a single die to provide further physical separation between the RF and/or other semiconductor devices in the first, horizontal directions (X-axis and Y-axis directions) to provide sufficient electrical isolation. An IC such as the IC 200 in FIG. 2A with its coupled bottom and top dies 202(1), 202(2) may increase the overall height of the IC 200 in the second, vertical direction (Z-axis direction), but with the benefit of the ability to include an increased number of devices in the IC 200 while still providing sufficient electrical isolation, as desired.

The bottom die 202(1) of the IC 200 in FIG. 2A will now be discussed in more detail with regard to FIG. 2A and the close-up side view of the bottom die 202(1) in FIG. 2B. As shown in FIGS. 2A and 2B, the IC 200 includes the bottom die 202(1). The bottom die 202(1) includes the first substrate 210(1) extending in the first directions (X-axis and Y-axis directions). In this example, the first substrate 210(1) is a SOI substrate that includes a semiconductor substrate 212 and a BIL 214 (e.g., a BOX layer). The BIL 214 is disposed in the semiconductor substrate 212 in the second, vertical direction (Z-axis direction), and the first semiconductor layer 206(1) is formed on the BIL 214. The BIL 214 provides additional isolation between the first semiconductor layer 206(1) and the semiconductor substrate 212. This may be desired, because in this example, the bottom die 202(1) can be made from a conventional semiconductor wafer that includes a semiconductor material that becomes the semiconductor substrate 212 after being diced. For example, the semiconductor substrate 212 may be a silicon substrate. Thus, the semiconductor substrate 212 is more susceptible to carriers being activated therein from charge build-up due to the intrinsic capacitance between the first semiconductor devices 204(1) and the semiconductor substrate 212. The first substrate 210(1) does not include a high resistivity layer (e.g., a trap rich layer) like in the IC 100 in FIG. 1.

With continuing reference to FIGS. 2A and 2B, the bottom die 202(1) includes the first interconnect structure 208(1). The first interconnect structure 208(1) has a first side 216(1) adjacent to the first substrate 210(1) and a second side 216(2) opposite the first side 216(1) in the second, vertical direction (Z-axis direction). The first semiconductor layer 206(1) is adjacent to the first side 216(1) of the first interconnect structure 208(1) in the second, vertical direction (Z-axis direction). The first semiconductor layer 206(1) includes the first semiconductor devices 204(1). For example, the first semiconductor devices 204(1) may be non-RF semiconductor devices that are not configured to be included in RF circuits, and thus are not configured to emit RF energy. For example, the first semiconductor devices 204(1) may be analog and/or digital devices that are configured to carry respective analog and/or digital signals that are not modulated and not RF or AC signals. In another example, one or more of the first semiconductor devices 204(1) could be RF semiconductor devices, but the location and layout of such RF semiconductor devices would be arranged so as to not cause an unacceptable amount of interference with other first semiconductor devices 204(1) formed in the first semiconductor layer 206(1).

FIG. 2B is a close-up side view of the bottom die 202(1) in the IC 200 in FIG. 2A to illustrate more exemplary detail of the first interconnect structure 208(1) and its design and connectivity to the first semiconductor devices 204(1) in the first semiconductor layer 206(1) and to be able to be coupled to the second interconnect structure 208(1) of the top die 202(2), as shown in FIG. 2A. In this regard, as shown in FIG. 2B, the first interconnect structure 208(1) includes a plurality of first metallization layers 218(1)-218(X). The first metallization layer 218(1) is an outer, first metallization layer 218(1) on the first side 216(1) of the first interconnect structure 208(1) adjacent to the first semiconductor layer 206(1) and the first substrate 210(1) in the second, vertical direction (Z-axis direction). The first metallization layer 218(X) is an inner, first metallization layer 218(X) on the second side 216(2) of the first interconnect structure 208(1) configured to be coupled to an adjacent respective inner, second metallization layer 238(Y) in the second interconnect structure 208(2) of the top die 202(2) in an interconnect top-to-top coupling configuration to couple the bottom and top dies 202(1), 202(2) as shown in FIG. 2A. Each first metallization layer 218(1)-218(X) includes a respective plurality of first metal interconnects 220(1)-220(X) formed in or adjacent to a respective first insulating layer 222(1)-222(X) and coupled to respective first vias 224(1)-224(X−1) formed in the respective first insulating layers 222(1)-222(X−1). The first interconnect structure 208(1) could be formed in a back-end-of-line (BEOL) process when fabricating the bottom die 202(1). The first interconnect structure 208(1) is designed so that the first metal interconnects 220(1)-220(X) are coupled to each other through the vias 224(1)-224(X−1) according to the signal routing paths desired to be provided to the first semiconductor devices 204(1) in the bottom die 202(1) through metal contacts 226 in a metal contact layer 228. As will be discussed below, the second side 216(2) of the first interconnect structure 208(1) is designed for its first metal interconnects 220(X) to be exposed from the first insulating layer 222(X) to allow the first metal interconnects 220(X) to be coupled to the second interconnect structure 208(2) of the top die 202(2) to couple the bottom and top dies 202(1), 202(2) together to form the IC 200.

The top die 202(2) of the IC 200 in FIG. 2A will now be discussed in more detail with regard to FIG. 2A and the close-up side view of the top die 202(2) in FIG. 2C. As shown in FIGS. 2A and 2C, the IC 200 includes the top die 202(2). The top die 202(2) is shown flipped upside down from the orientation of the bottom die 202(1) in FIGS. 2A and 2B with its second substrate 210(2) above the second interconnect structure 208(2) in the second, vertical direction (Z-axis direction). The top die 202(2) includes the second substrate 210(2) extending in the first directions (X-axis and Y-axis directions). In this example, the second substrate 210(2) is also a SOI substrate that includes a second BIL 230 (e.g., a BOX layer) adjacent to the second semiconductor layer 206(2) such that the second semiconductor layer 206(2) is formed on the second BIL 230. The second BIL 230 provides additional isolation between the second semiconductor layer 206(2) and the second substrate 210(2). This may be desired, because in this example, the top die 202(2) can be made from a conventional semiconductor wafer that includes a semiconductor material. The second substrate 210(2) does not include a high resistivity layer (e.g., a trap rich layer) like in the IC 100 in FIG. 1. However, in this example, to provide enhanced isolation between the second, RF semiconductor devices 204(2) in the top die 202(2), the second substrate 210(2) includes a passivation substrate 232 that includes multiple passivation layers 234(1), 234(2) each made from a dielectric material that is not a semiconductor material. As discussed in more detail below, this option is possible, because the top die 202(2) is formed from a second wafter disposed on a first wafter that becomes the bottom die 202(1) in a fabrication process. Thus, the bottom die 202(1) provides support for the fabrication of the top die 202(2) such that a carrier substrate is not required for the top die 202(2). Thus, what would be a semiconductor substrate in the top die 202(2) (like the semiconductor substrate 212 in the bottom die 202(1)) can be removed and the passivation layers 234(1), 234(2) formed on the second interconnect structure 208(2) to provide enhanced electrical isolation.

With continuing reference to FIGS. 2A and 2C, the top die 202(2) includes the second interconnect structure 208(2). The second interconnect structure 208(2) has a third side 236(1) adjacent to the second substrate 210(2) and a fourth side 236(2) opposite the third side 236(1) in the second, vertical direction (Z-axis direction). The second semiconductor layer 206(2) is adjacent to the third side 236(1) of the second interconnect structure 208(2) in the second, vertical direction (Z-axis direction). The second semiconductor layer 206(2) includes the second, RF semiconductor devices 204(2) that are configured to emit RF energy. For example, the second, RF semiconductor devices 204(2) could include RF switches and/or RF amplifiers (low-noise amplifiers) as non-limiting examples. The second semiconductor layer 206(2) could also include second semiconductor devices 204(2) that are not RF semiconductor devices not configured to emit RF energy, if desired.

FIG. 2C is a close-up side view of the top die 202(2) in the IC 200 in FIG. 2A to illustrate more exemplary detail of the second interconnect structure 208(2) and its design and connectivity to the second, RF semiconductor devices 204(2) in the second semiconductor layer 206(2) and to be able to be coupled to the first interconnect structure 208(1) of the bottom die 202(1), as shown in FIG. 2A. In this regard, as shown in FIG. 2C, the second interconnect structure 208(2) includes a plurality of second metallization layers 238(1)-238(Y). The second metallization layer 238(1) is an outer, second metallization layer 238(1) on the third side 236(1) of the second interconnect structure 208(2) adjacent to the second semiconductor layer 206(2) and the second substrate 210(2) in the second, vertical direction (Z-axis direction). The second metallization layer 238(Y) is an inner, second metallization layer 238(Y) on the fourth side 236(2) of the second interconnect structure 208(2) configured to be coupled to an adjacent respective inner, first metallization layer 218(X) in the first interconnect structure 208(1) of the bottom die 202(1) in an interconnect top-to-top coupling configuration to couple the bottom and top dies 202(1), 202(2) as shown in FIG. 2A. Each second metallization layer 238(1)-238(Y) includes a respective plurality of second metal interconnects 240(1)-240(Y) formed in or adjacent to a respective second insulating layer 242(1)-242(Y) and coupled to respective second vias 244(1)-244(Y) formed in the respective second insulating layers 242(1)-242(Y). The second interconnect structure 208(2) could be formed in a BEOL process when fabricating the top die 202(2). The second interconnect structure 208(2) is designed so that the second metal interconnects 240(1)-240(Y) are coupled to each other through the vias 244(1)-244(Y) according to the signal routing paths desired to be provided to the second, RF semiconductor devices 204(2) in the top die 202(2) through metal contacts 246 in a metal contact layer 248.

As shown in FIG. 2A, the fourth side 236(2) of the second interconnect structure 208(2) is designed for its inner, second vias 244(Y) to be exposed from the inner, second insulating layer 242(Y) to allow the second vias 244(Y) to be coupled to inner, first metal interconnects 220(X) of the inner, first interconnect structure 208(1) of the bottom die 202(1). This is accomplished by coupling the second and fourth sides 216(2), 236(2) of the respective first and second interconnect structures 208(1), 208(2) together to couple the second vias 244(Y) to first metal interconnects 220(X) to couple the bottom and top dies 202(1), 202(2) together to form the IC 200. In this example, the second vias 244(Y) are directly coupled to the first metal interconnects 220(X) in a metal-to-metal bonding. For example, the second and fourth sides 216(2), 236(2) of the respective first and second interconnect structures 208(1), 208(2) can be compressed against each other to compress the second vias 244(Y) to the first metal interconnects 220(X) to achieve a compression bond between them.

Then, as shown in FIG. 2A, to provide external signal routing paths to the IC 200, vias 250 are formed in the second, vertical direction (Z-axis direction) through the passivation layers 234(1), 234(2), the BIL 230 and the second semiconductor layer 206(2) to be coupled to outer, second metal interconnects 240(2) in the outer, second metallization layer 238(2) of the second interconnect structure 208(2). External interconnects 252 (e.g., solder balls, BGA interconnects) are formed in openings 254 in the passivation layer 234(2) in contact with the vias 250 to provide signal routing paths between the external interconnects 252 and the top die 202(2). As discussed above, the coupling of the inner, second vias 244(Y) to the inner, first metal interconnects 220(X) can extend these signal routing paths between the external interconnects 252 and the bottom die 202(1).

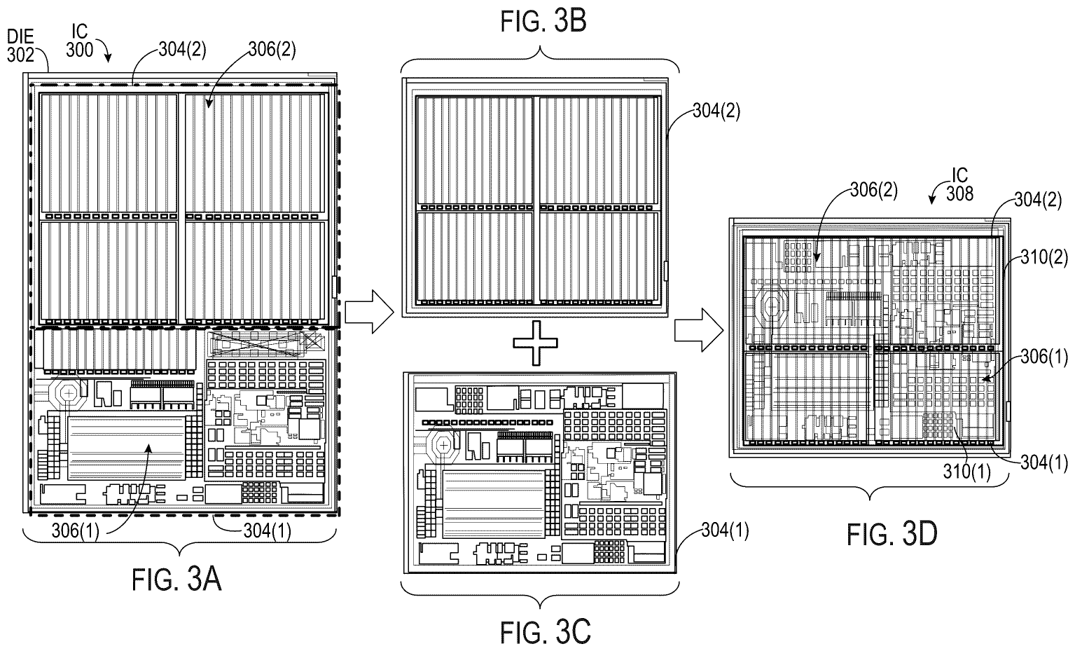

The exemplary aspects of the design of the IC 200 can be used to redesign existing single die ICs that include RF semiconductor devices to provide enhanced electrical isolation of such RF semiconductor devices from other semiconductor devices. In this regard, FIGS. 3A-3C are top views of an exemplary layout of an exemplary IC 300 that is provided in a single die 302. The die 302 includes a first circuit section 304(1) that includes non-RF semiconductor devices 306(1), and a second circuit section 304(2) that includes RF semiconductor devices 306(2). FIGS. 3B and 3C illustrate the separation of the respective first and second circuit sections 304(1), 304(2) in the IC 300 in FIG. 3A. FIG. 3D is a top view of another exemplary IC 308 that includes a second, top die 310(2) having the second circuit section 304(2) in FIG. 3B coupled to a separate, first, bottom die 310(1) having the first circuit section 304(1) in FIG. 3C coupled to each other in the second, vertical direction (Z-axis direction) in a top-to-top coupling configuration to provide enhanced electrical isolation between the RF semiconductor devices 306(2) in the top die 310(2) and other semiconductor devices 306(1) in the bottom die 310(1).

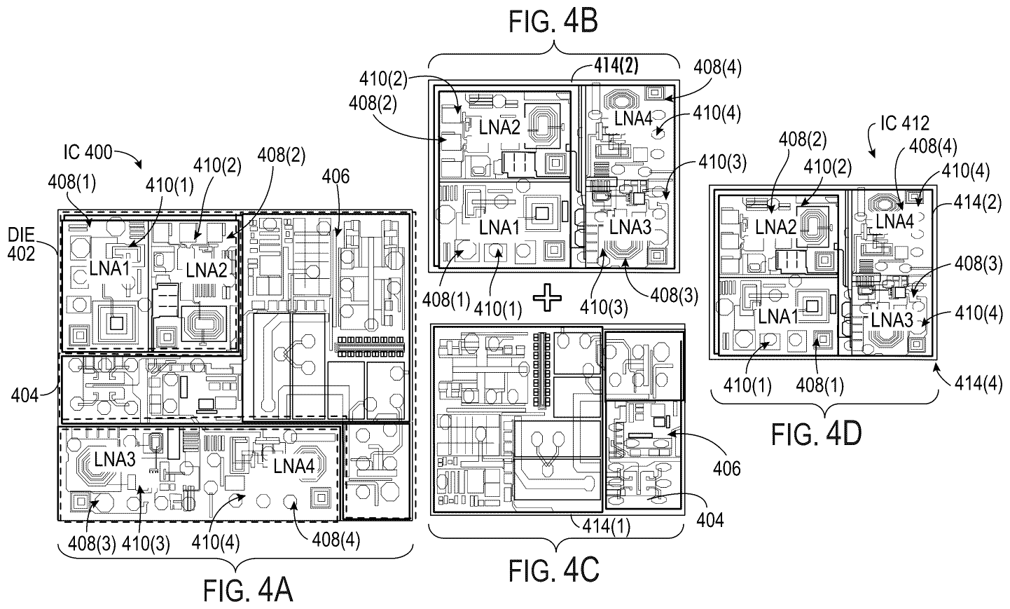

FIGS. 4A-4C are top views of an exemplary layout of another exemplary IC 400 that is provided in a single die 402. The die 402 includes a first circuit section 404 that includes non-RF semiconductor devices 406, and second circuit sections 408(1)-408(4) that includes LNAs 410(1)-410(4). FIGS. 4B and 4C illustrate the separation of the respective first and second circuit sections 404, 408(1)-408(4) in the IC 400 in FIG. 4A. FIG. 4D is a top view of another exemplary IC 412 that includes a second, top die 414(2) having the second circuit sections 408(1)-408(4) in FIG. 4B coupled to a separate, bottom die 414(1) having the first circuit section 404 in FIG. 4C coupled to each other in the second, vertical direction (Z-axis direction) in a top-to-top coupling configuration to provide enhanced electrical isolation between the LNAs 410(1)-410(4) in the top die 414(2) and other semiconductor devices 406 in the bottom die 414(1).

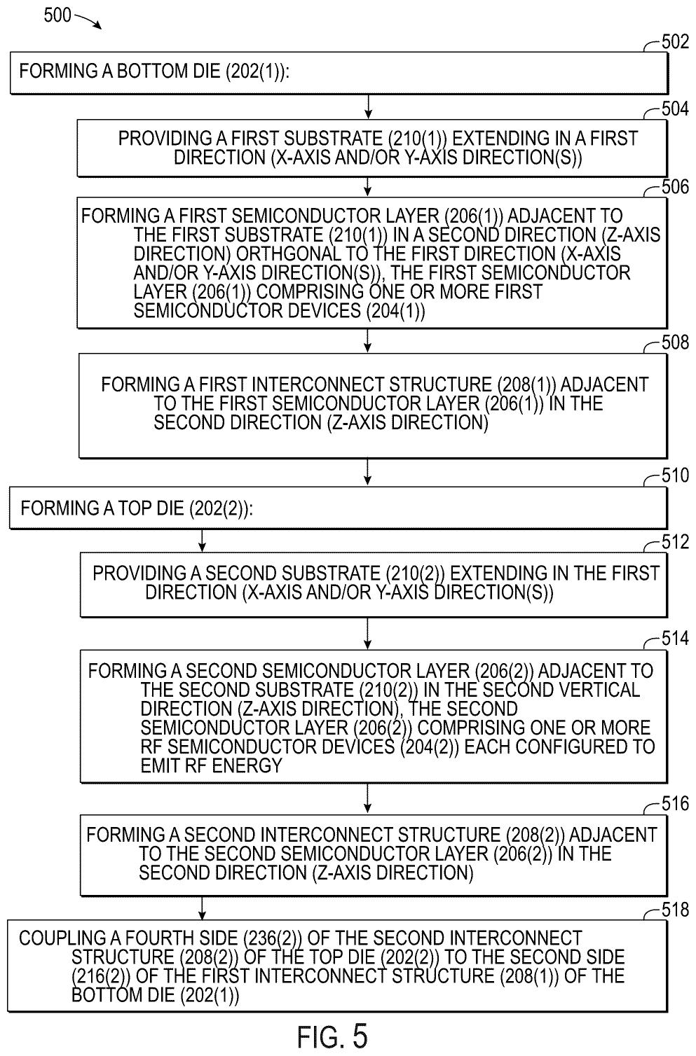

ICs that each include a bottom die with first, semiconductor devices formed in a first semiconductor layer and a second, top die with second, RF semiconductor devices formed therein formed in a second semiconductor layer, and wherein first and second interconnect structures of the respective bottom and top dies are coupled to each other in a vertical direction in a top-to-top coupling configuration to provide enhanced electrical isolation between second, RF semiconductor devices in the top die, and the first semiconductor devices in the first, bottom die, including, but not limited to, the ICs 200, 308, 412 and dies 202(1), 202(2), 310(1), 310(2), 414(1), 414(2) in FIGS. 2A-2C, 3D and 4D, can be fabricated according to a fabrication process. In this regard, FIG. 5 is a flowchart illustrating an exemplary fabrication process 500 of fabricating ICs that each include a bottom die with first, semiconductor devices formed in a first semiconductor layer and a top die with second, RF semiconductor devices formed therein formed in a second semiconductor layer, and wherein first and second interconnect structures of the respective bottom and top dies are coupled to each other in a vertical direction in a top-to-top coupling configuration to provide enhanced electrical isolation between second, RF semiconductor devices in the top die, including, but not limited to, the ICs 200, 308, 412 and dies 202(1), 202(2), 310(1), 310(2), 414(1), 414(2) in FIGS. 2A-2C, 3D and 4D. The fabrication process 500 in FIG. 5 is described with regard to the exemplary IC 200 in FIGS. 2A-2C, but such is not limiting.

In this regard, as shown in FIG. 5, a first step of the fabrication process 500 can be forming the bottom die 202(1) (block 502 in FIG. 5). Forming the bottom die 202(1) can include providing a first substrate 210(1) extending in the first, horizontal direction (X-axis and/or Y-axis direction(s)) (block 504 in FIG. 5). Forming the bottom die 202(1) can also include forming the first semiconductor layer 206(1) adjacent to the first substrate 210(1) in the second, vertical direction (Z-axis direction) orthogonal to the first, horizontal direction(s) (X-axis and/or Y-axis direction(s)), wherein the first semiconductor layer comprises one or more first semiconductor devices 204(1) (block 506 in FIG. 5). Forming the bottom die 202(1) can also include forming the first interconnect structure 208(1) adjacent to the first semiconductor layer 206(1) in the second, vertical direction (Z-axis direction), such that the first side 216(1) of the first interconnect structure 208(1) is adjacent to the first semiconductor layer 206(1) in the second, vertical direction (Z-axis direction) (block 508 in FIG. 5). The first side 216(1) of the first interconnect structure 208(1) is opposite the second side 216(2) of the first interconnect structure 208(1) in the second, vertical direction (Z-axis direction).

A next step of the fabrication process 500 can be forming the top die 202(2) (block 510 in FIG. 5). Forming the top die 202(2) can include providing a second substrate 210(2) extending in the first, horizontal direction (X-axis and/or Y-axis direction(s)) (block 512 in FIG. 5). Forming the top die 202(2) can also include forming the second semiconductor layer 206(2) adjacent to the second substrate 210(2) in the second, vertical direction (Z-axis direction), wherein the second semiconductor layer 206(2) comprises one or more second, RF semiconductor devices 204(2) (block 514 in FIG. 5). Forming the top die 202(2) can also include forming the second interconnect structure 208(2) adjacent to the second semiconductor layer 206(2) in the second, vertical direction (Z-axis direction), such that the third side 236(1) of the second interconnect structure 208(2) is adjacent to the second semiconductor layer 206(2) in the second, vertical direction (Z-axis direction) (block 516 in FIG. 5). The third side 236(1) of the second interconnect structure 208(2) is opposite the fourth side 236(2) of the second interconnect structure 208(2) in the second, vertical direction (Z-axis direction).

A next step in forming the IC 200 is coupling the fourth side 236(2) of the second interconnect structure 208(2) of the top die 202(2) to the second side 216(2) of the first interconnect structure 208(1) of the bottom die 202(1) (block 518 in FIG. 5).

ICs that each include a first, bottom die with first, semiconductor devices formed in a first semiconductor layer and a second, top die with second, RF semiconductor devices formed therein formed in a second semiconductor layer, and wherein first and second interconnect structures of the respective bottom and top dies are coupled to each other in a vertical direction in a top-to-top coupling configuration to provide enhanced electrical isolation between second, RF semiconductor devices in the top die, and the first semiconductor devices in the bottom die, including, but not limited to, the ICs 200, 308, 412 and dies 202(1), 202(2), 310(1), 310(2), 414(1), 414(2) in FIGS. 2A-2C, 3D and 4D, can be fabricated according to other fabrication processes.

For example, the IC could be fabricated in a wafer-to-wafer bonding process for efficient fabrication and so that readily available semiconductor wafers can be used to form bottom and top dies that contain their respective first semiconductor devices and second, RF semiconductor devices with readily available wafer processing techniques. In this regard, a first, bottom wafer can be provided in which first semiconductor devices are formed in a first semiconductor layer therein and the first interconnect structure is then formed on the first semiconductor layer and then diced into a plurality of the first, bottom dies. Before the bottom wafer is diced, a second top wafer can be provided in which second, RF semiconductor devices are formed in a second semiconductor layer and the second interconnect structure is then formed on the second semiconductor layer. Metal interconnects on the outer metallization layers of the first and second interconnect structures of the respective bottom and top wafers can then be exposed and the top wafer flipped and its outer metallization layer coupled (e.g., bonded) to the outer metallization layer of the bottom wafer in a top-to-top coupling configuration. Exposed metal interconnects from each outer metallization layer of the bottom and top wafers are coupled (e.g., bonded) to each other as a result of coupling the outer metallization layers of the respective first and second interconnect structures of the bottom and top wafers to form signal routing paths between the bottom and top wafers and thus respective first semiconductor devices and second, RF semiconductor devices.

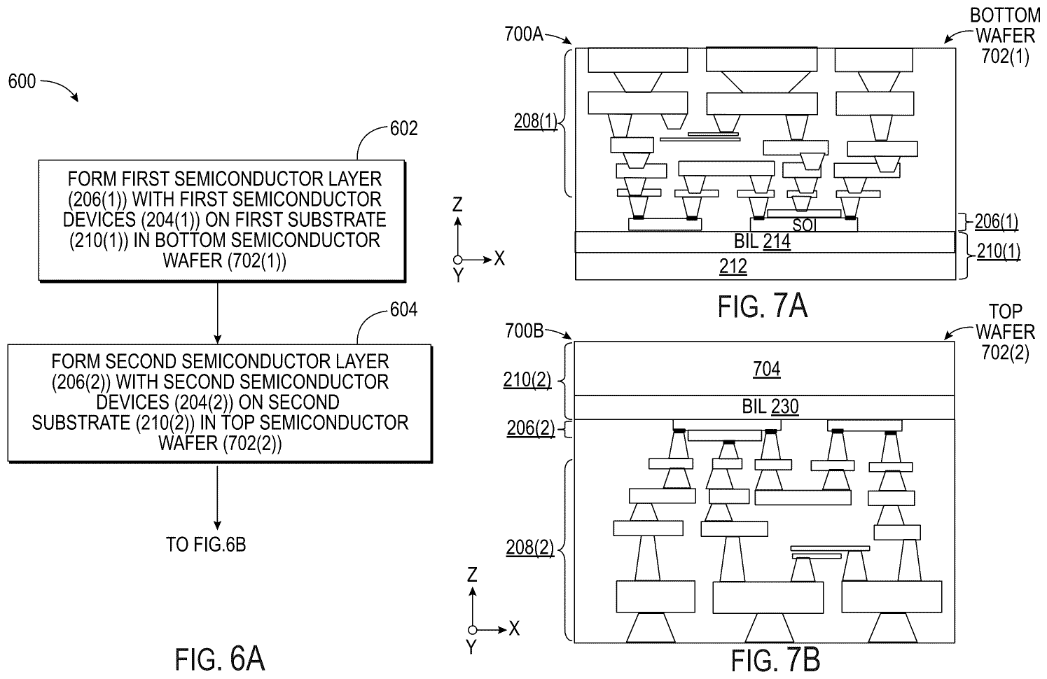

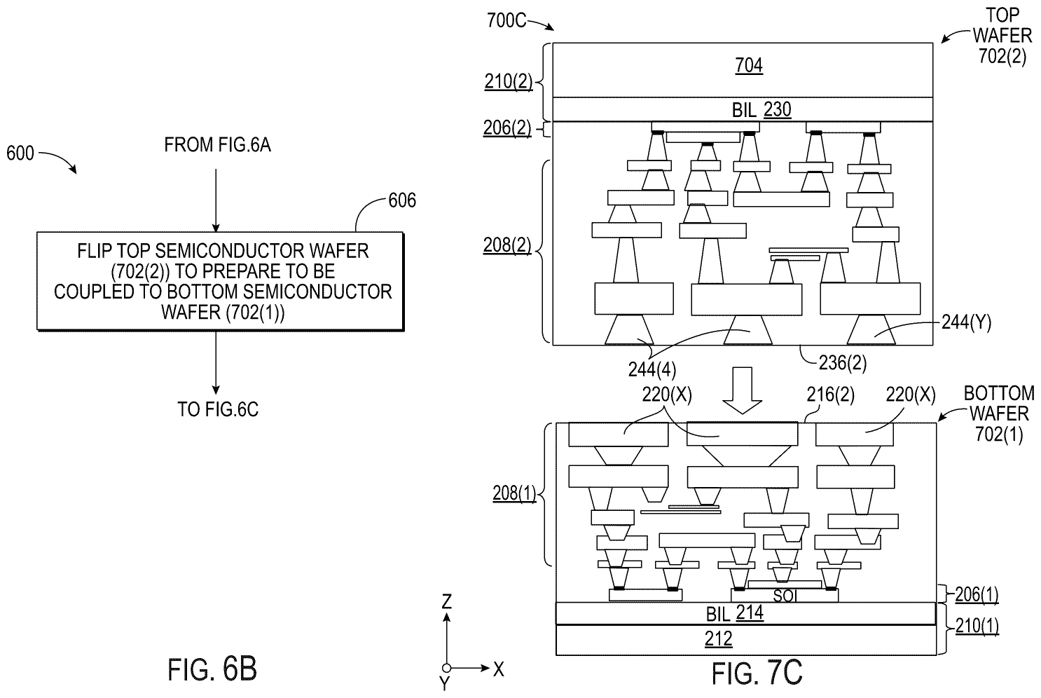

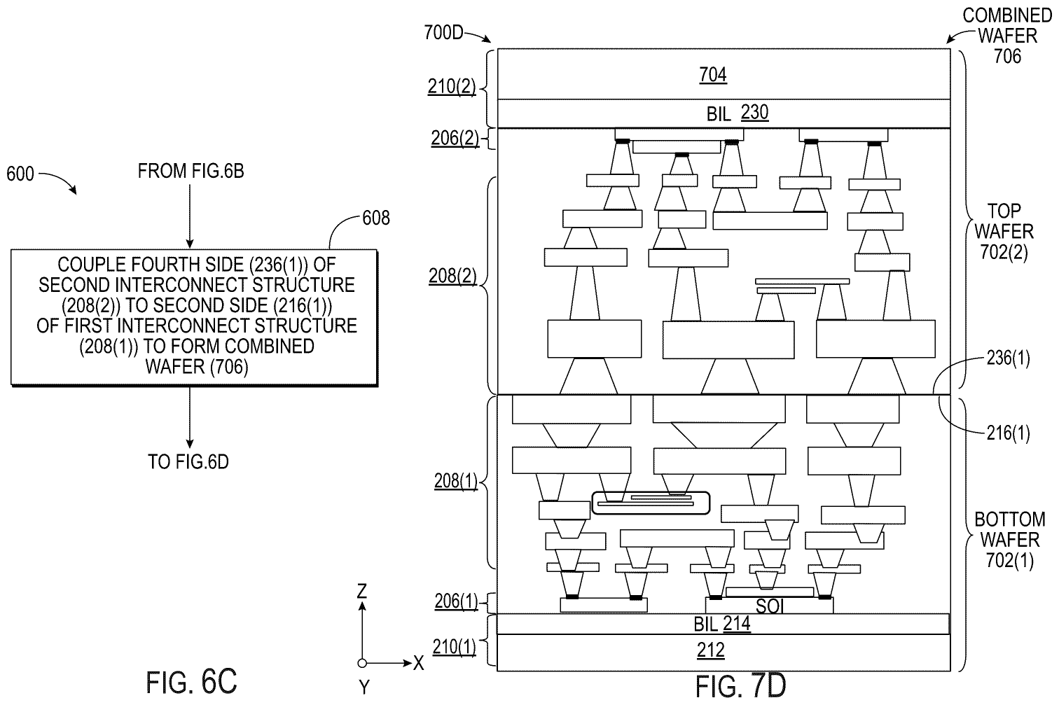

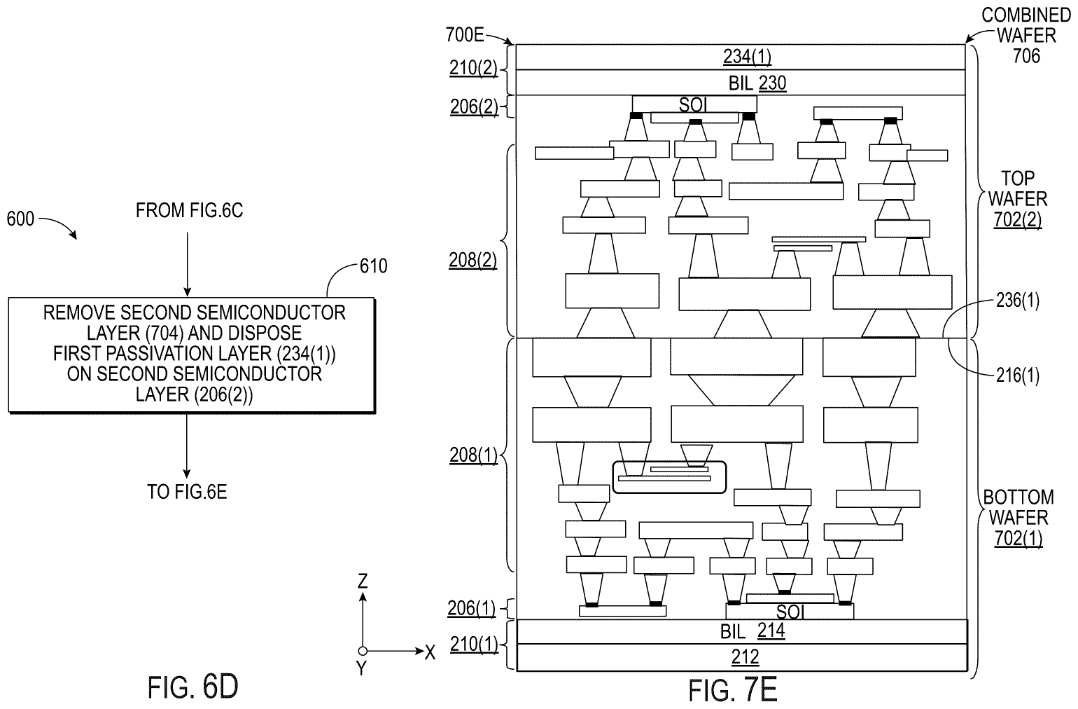

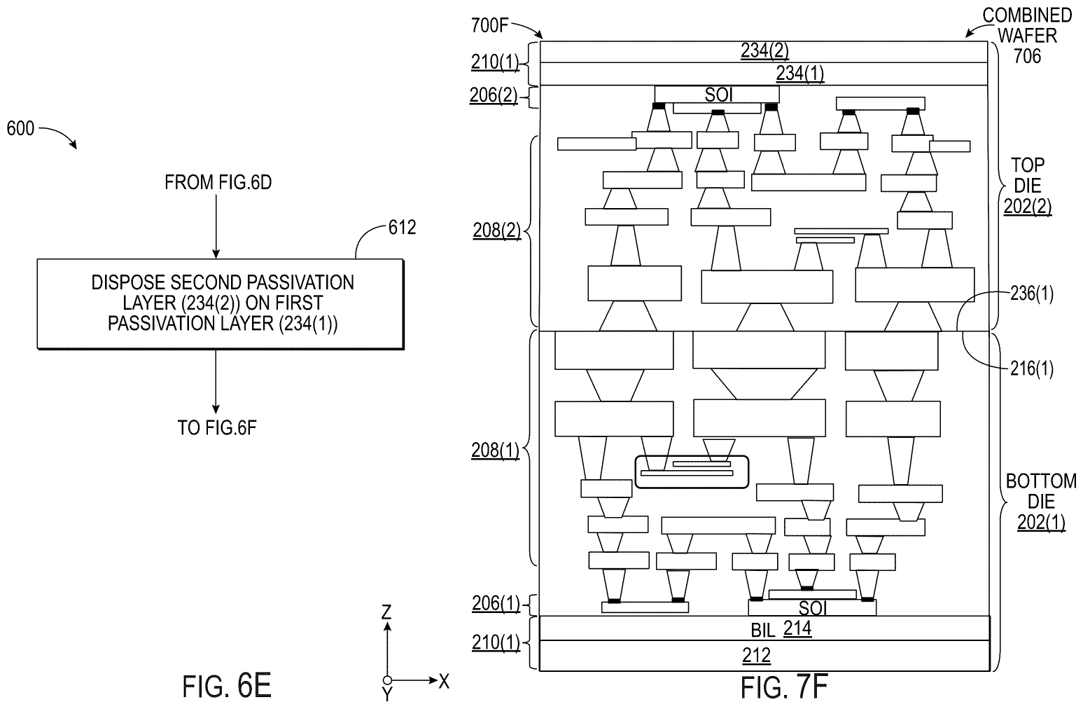

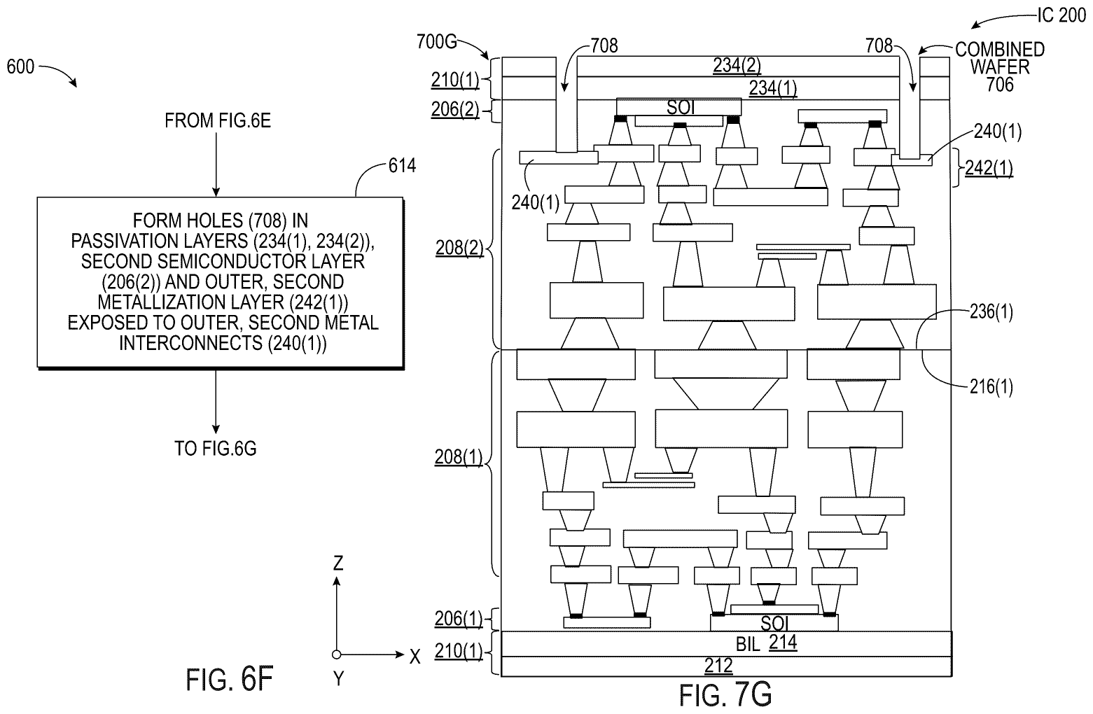

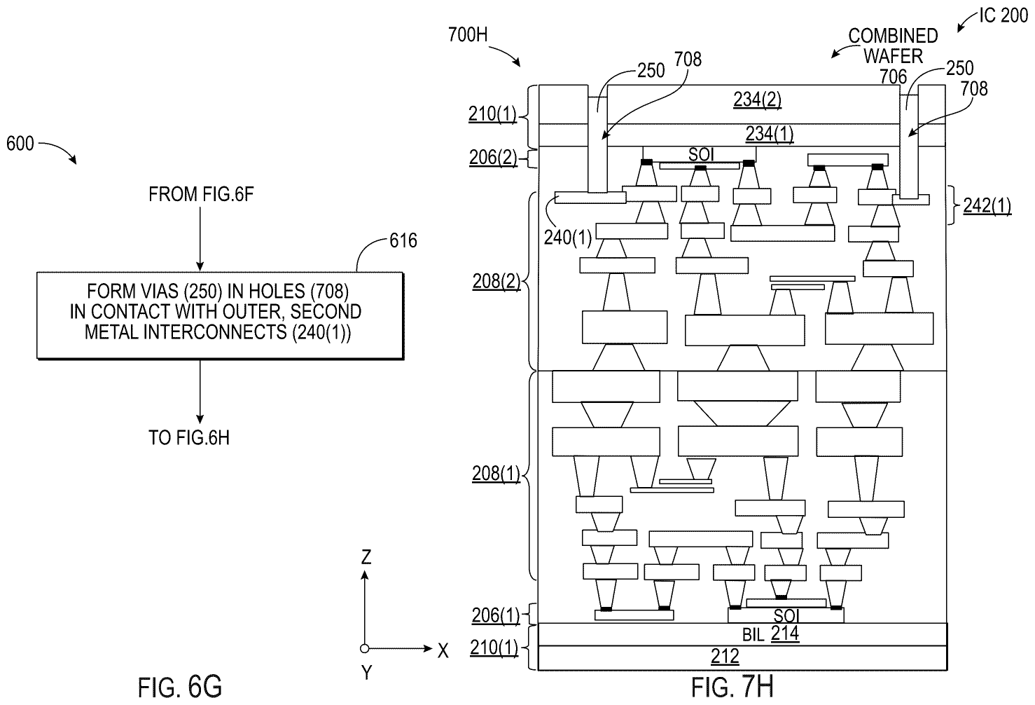

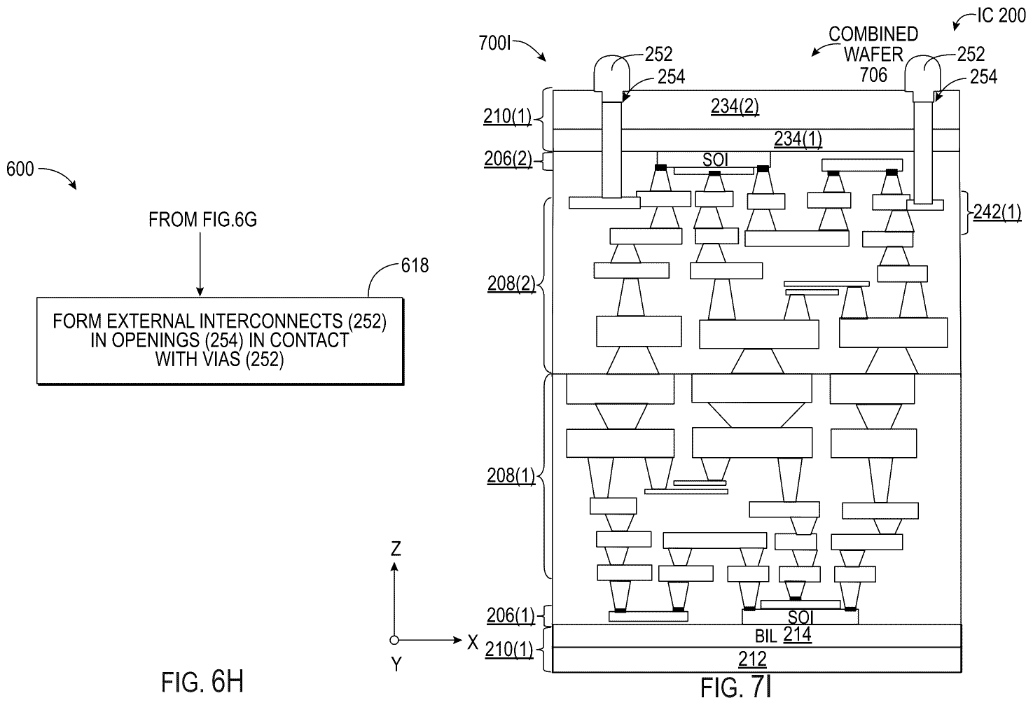

For example, FIGS. 6A-6H is a flowchart illustrating another exemplary fabrication process 600 of fabricating an IC that includes a first, bottom wafer with first, semiconductor devices formed in a first semiconductor layer and a second, top wafer with second, RF semiconductor devices formed therein formed in a second semiconductor layer in a wafer-to-wafer fabrication process. As discussed in more detail below, the first and second interconnect structures of the respective bottom and top wafers are coupled to each other in a vertical direction in a top-to-top coupling configuration to provide enhanced electrical isolation between second, RF semiconductor devices in the top wafer, and the first semiconductor devices in the bottom wafer. The combined wafer can then be diced into ICs like, but not limited to, the ICs 200, 308, 412 and dies 202(1), 202(2), 310(1), 310(2), 414(1), 414(2) in FIGS. 2A-2C, 3D and 4D. FIGS. 7A-7I are exemplary fabrication stages 700A-700I during fabrication of the wafers to be diced into ICs according to the exemplary fabrication process 600 in FIGS. 6A-6H. The fabrication process 600 in FIGS. 6A-6H that can fabricate multiple ICs is discussed below with reference to the exemplary IC 200 in FIGS. 2A-2C, but such is not limiting and could be used to fabricate other ICs. The fabrication process 600 is discussed in regard to fabricating a single IC 200, but note that the bonded wafers will form multiple ICs after being diced.

In this regard, as shown in the exemplary fabrication stage 700A in FIG. 7A, a first step in the fabrication process 600 of the ICs 200 can be to form the first semiconductor layer 206(1) with the first semiconductor devices 204(1) disposed therein on the first substrate 210(1) that includes the semiconductor layer 212 in a first, bottom semiconductor wafer 702(1), and to form the first interconnect structure 208(1) on the first semiconductor layer 206(1) (block 602 in FIG. 6A). The bottom semiconductor wafer 702(1) will be diced after being coupled to a second, top wafer to form the bottom and top dies 202(1), 202(2) coupled to each other. As shown in the exemplary fabrication stage 700B in FIG. 7B, a next step in the fabrication process 600 of the ICs 200 can be to form the second semiconductor layer 206(2) with the second, RF semiconductor devices 204(2) disposed therein on the second substrate 210(2) in a top semiconductor wafer 702(2), and to form the second interconnect structure 208(2) on the second semiconductor layer 206(2) (block 604 in FIG. 6A). Note that the second substrate 210(2) is a second semiconductor substrate 704 like the semiconductor substrate 212 of the bottom semiconductor wafer 702(1) at this phase of fabrication.

As shown in the exemplary fabrication stage 700C in FIG. 7C, a next step in the fabrication process 600 of the ICs 200 is to flip the top semiconductor wafer 702(2) to prepare the fourth side 236(2) of the second interconnect structure 208(2) of the top semiconductor wafer 702(2) to be coupled to the second side 216(2) of the first interconnect structure 208(1) of the bottom semiconductor wafer 702(1) (block 606 in FIG. 6B). Then, as shown in the exemplary fabrication stage 700D in FIG. 7D, a next step of the fabrication process 600 of the ICs 200 is to couple the fourth side 236(2) of the second interconnect structure 208(2) and its exposed second vias 244(Y) of the top semiconductor wafer 702(2), to the second side 216(2) of the first interconnect structure 208(1) and its exposed first metal interconnects 220(X) to form a combined semiconductor wafer 706 (block 608 in FIG. 6C).

As previously discussed above, in the example of the IC 200 in FIG. 2A, it may be desired to remove the second semiconductor substrate 704 and replace it with the passivation layers 234(1), 234(2) to provide further enhanced electrical isolation of the second, RF semiconductor devices 204(2) formed in the second semiconductor layer 206(2) of the top semiconductor wafer 702(2). In this regard, as shown in the exemplary fabrication stage 700E in FIG. 7E, the second semiconductor substrate 704 can be removed (e.g., by grinding or other processing), and the first passivation layer 234(1) is disposed on the second semiconductor layer 206(2) (block 610 in FIG. 6D). Then, as shown in the exemplary fabrication stage 700F in FIG. 7F, the second passivation layer 234(2) is disposed on the first passivation layer 234(1) (block 612 in FIG. 6E).

At fabrication stage 700F in FIG. 7F, the combined semiconductor wafer 706 is fully formed. The combined semiconductor wafer 706 can now be diced to form ICs 200 each with a top die 202(2) formed in the top semiconductor wafer 702(2) coupled to a bottom die 202(1) formed in the bottom semiconductor wafer 702(1). This is shown in the exemplary fabrication stage 700G in FIG. 7G. Also, as previously discussed in regard to FIG. 2A, it is desired to from external interconnects 252 coupled to outer, second metal interconnects 240(1) in the outer, second metallization layer 238(1) to provide external access to signal routing paths to the first and second, RF semiconductor devices 204(1), 204(2). In this regard, as shown in exemplary fabrication stage 700G in FIG. 7G, a next step can be to form holes 708 in the first and second passivation layers 234(1), 234(2), the second semiconductor layer 206(2), and the outer, second metallization layer 238(1) of the top die 202(2) of the IC 200 that expose outer, second metal interconnects 240(1) with openings 254 to the holes 708 exposed through the second passivation layer 234(2) (block 614 in FIG. 6F). For example, the holes 708 may be formed by drilling holes into the first and second passivation layers 234(1), 234(2) and the outer, second metallization layer 238(1). Then, as shown in exemplary fabrication stage 700H in FIG. 7H, a next step can be to form vias 250 in the openings 254 coupled to the outer, second metal interconnects 240(1) in the outer, second metallization layer 238(1) of the top die 202(2) (block 616 in FIG. 6G). Then, as shown in exemplary fabrication stage 700I in FIG. 7I, a next step can be to form the external interconnects 252 in the openings 254 coupled to the vias 250 of the top die 202(2) to provide for the external interconnects 252 to be electrically coupled to outer, second metal interconnects 240 in the outer, second metallization layer 238(1) of the top die 202(2) of the IC 200 (block 618 in FIG. 6H).

An IC that includes a first, bottom die with first, semiconductor devices formed in a first semiconductor layer and a second, top die with second, RF semiconductor devices formed therein formed in a second semiconductor layer, and wherein first and second interconnect structures of the respective bottom and top dies are coupled to each other in a vertical direction in a top-to-top coupling configuration to provide enhanced electrical isolation between second, RF semiconductor devices in the top die, and the first semiconductor devices in the bottom die, including, but not limited to, the ICs 200, 308, 412 and dies 202(1), 202(2), 310(1), 310(2), 414(1), 414(2) in FIGS. 2A-2C, 3D and 4D, and according to any aspects disclosed herein, that can be fabricated according to a fabrication process, including, but not limited to, the exemplary fabrication processes 500, 600 in FIGS. 5-6H may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

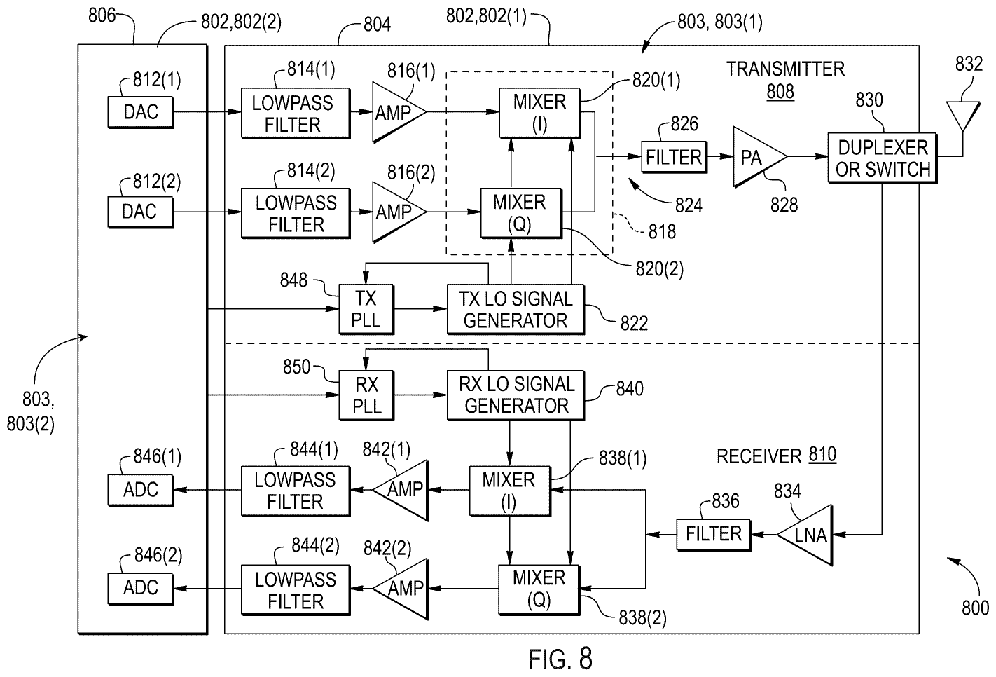

In this regard, FIG. 8 illustrates an exemplary wireless communications device 800 that includes one or more IC packages 802, 802(1), 802(2) that each include an IC 803, 803(1), 803(2), including, but not limited to, the ICs 200, 308, 412 and their dies 202(1), 202(2), 310(1), 310(2), 414(1), 414(2) in FIGS. 2A-2C, 3D, 4D, and 7D-7I, wherein the ICs 803, 803(1), 803(2) include a first, bottom die with first, semiconductor devices formed in a first semiconductor layer and a second, bottom die with second, RF semiconductor devices formed therein formed in a second semiconductor layer, and wherein first and second interconnect structures of the respective bottom and top dies are coupled to each other in a vertical direction in a top-to-top coupling configuration to provide enhanced electrical isolation between second, RF semiconductor devices in the top die, and the first semiconductor devices in the bottom die. The IC packages 802, 802(1), 802(2) and their ICs 803, 803(1), 803(2) can be fabricated according to a fabrication process, including, but not limited to, the exemplary fabrication processes 500, 600 in FIGS. 5-6H, and according to any aspects disclosed herein.

The wireless communications device 800 may include or be provided in any of the above-referenced devices, as examples. As shown in FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communication systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 810. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into the I and Q analog output signals, e.g., I and Q output currents, for further processing.

Within the transmitter 808, lowpass filters 814(1), 814(2) filter the I and Q analog output signals, respectively, to remove undesired signals caused by the prior digital-to-analog conversion. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals through mixers 820(1), 820(2) from a TX LO signal generator 822 to provide an upconverted signal 824. A filter 826 filters the upconverted signal 824 to remove undesired signals caused by the frequency upconversion as well as noise in a receive frequency band. For example, the filter 826 can be a RF semiconductor device that is provided in a top die of the IC 803(1) separated from other semiconductor devices provided in a bottom die of the IC 803(1) coupled to the top die. A power amplifier (PA) 828 amplifies the upconverted signal 824 from the filter 826 to obtain the desired output power level and provides a transmit RF signal. For example, the PA 828 can be a RF semiconductor device that is provided in a top die of the IC 803(1) separated from other semiconductor devices provided in a bottom die of the IC 803(1) coupled to the top die. The transmit RF signal is routed through a duplexer or switch 830 and transmitted via an antenna 832. For example, the duplexer or switch 830 can be a RF semiconductor device that is provided in a top die of the IC 803(1) separated from other semiconductor devices provided in a bottom die of the IC 803(1) coupled to the top die.

In the receive path, the antenna 832 receives signals transmitted by base stations and provides a received RF signal, which is routed through the duplexer or switch 830 and provided to a low noise amplifier (LNA) 834. For example, the LNA 834 can be a RF semiconductor device that is provided in a top die of the IC 803(1) separated from other semiconductor devices provided in a bottom die of the IC 803(1) coupled to the top die. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. For example, the filter 836 can be a RF semiconductor device that is provided in a top die of the IC 803(1) separated from other semiconductor devices provided in a bottom die of the IC 803(1) coupled to the top die. Downconversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency upconversion, while the RX LO signal generator 840 generates the I and Q RX LO signals used for frequency downconversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

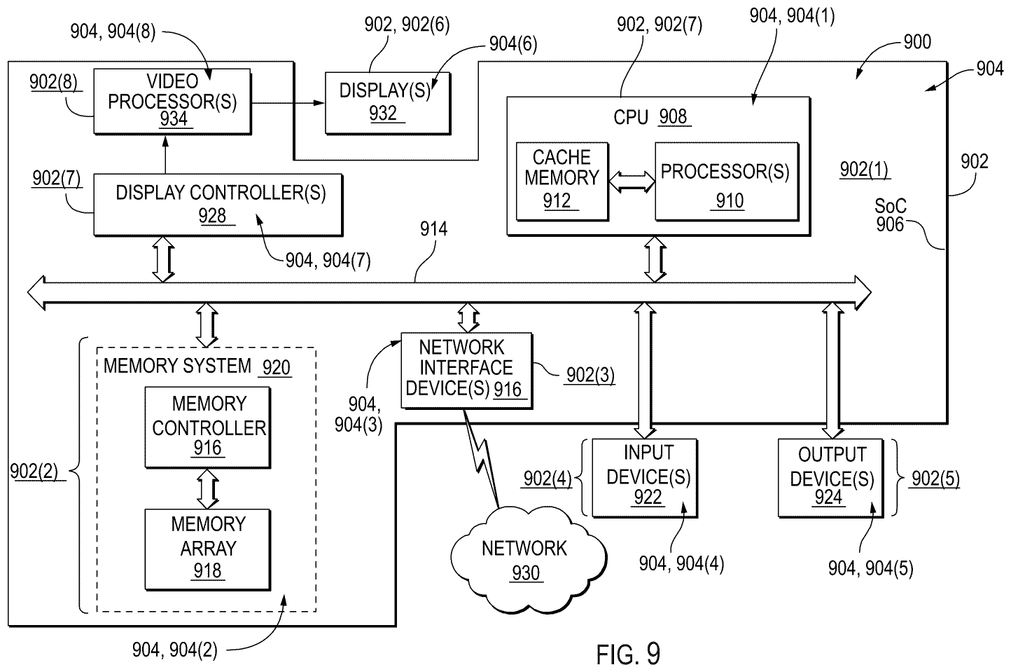

FIG. 9 illustrates an example of a processor-based system 900 that includes one or more IC packages 902, 902(1)-902(8) that each include a IC 904, 904(1)-904(8), including, but not limited to, the ICs 200, 308, 412 and their dies 202(1), 202(2), 310(1), 310(2), 414(1), 414(2) in FIGS. 2A-2C, 3D, 4D, and 7D-7I, wherein the ICs 904, 904(1)-904(8) include a first, bottom die with first, semiconductor devices formed in a first semiconductor layer and a second, top die with second, RF semiconductor devices formed therein formed in a second semiconductor layer, and wherein first and second interconnect structures of the respective bottom and top dies are coupled to each other in a vertical direction in a top-to-top coupling configuration to provide enhanced electrical isolation between second, RF semiconductor devices in the top die, and the first semiconductor devices in the bottom die. The IC packages 902, 902(1)-902(8) and their ICs 904, 904(1)-904(8) can be fabricated according to a fabrication process, including, but not limited to, the exemplary fabrication processes 500, 600 in FIGS. 5-6H, and according to any aspects disclosed herein.

In this example, the processor-based system 900 may include an IC 904 that is included in an IC package 902, such as a system-on-a-chip (SoC) 906. The processor-based system 900 includes a CPU 908 that includes one or more processors 910, which may also be referred to as CPU cores or processor cores. The CPU 908 can be provided in an IC package 902(1) that includes the IC 904(1). The CPU 908 may have cache memory 912 coupled to the CPU 908 for rapid access to temporarily stored data. The CPU 908 is coupled to a system bus 914 and can intercouple master and slave devices included in the processor-based system 900. As is well known, the CPU 908 communicates with these other devices by exchanging address, control, and data information over the system bus 914. For example, the CPU 908 can communicate bus transaction requests to a memory controller 916 as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that includes the memory controller 916 and a memory array(s) 918, one or more input devices 922, one or more output devices 924, one or more network interface devices 926, and one or more display controllers 928, as examples. The memory system 920 can be provided in an IC package 902(2) that includes the IC 904(2). The network interface devices 926 can be provided in an IC package 902(3) that includes the IC 904(3). Each of the memory system 920, the one or more input devices 922, the one or more output devices 924, the one or more network interface devices 926, and the one or more display controllers 928 can be provided in the same or different circuit packages. The input devices 922 and/or the output devices 924 can be provided in a respective IC package 902(4), 902(5) that includes a respective IC 904(4), 904(5). The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display(s) 932 can be provided in an IC package 902(6) that includes the IC 904(6). The display controller(s) 928 sends information to the display(s) 932 to be displayed via one or more video processors 934, which process the information to be displayed into a format suitable for the display(s) 932. The display controller(s) 928 and video processor(s) 934 can be provided in a respective IC package 902(7), 902(8) that includes the ICs 904(7), 904(8), or be provided in the same IC package 902, or be provided in the same IC package 902(1) containing the CPU 908 as an example. The display(s) 932 can include any type of display, including, but not limited to, a cathode ray tube (CRT), a liquid crystal display (LCD), a plasma display, a light emitting diode (LED) display, etc.

It should be understood that the terms “first,” “second,” “third,” etc., where used herein, are relative terms and are not meant to limit or imply a strict orientation. It should also be understood that that the terms “top,” “upper,” “above,” and “bottom,” “lower,” “below,” where used herein, are relative terms and are not meant to limit or imply a strict orientation. A “top” or “upper” or “above” referenced element does not always need to be oriented to be above a “bottom,” or “lower,” or “below” referenced element with respect to ground, and vice versa. An element referenced as “top,” “upper,” “above,” or “bottom,” “lower,” “below,” may be on top or bottom relative to that example only and the particular illustrated example. An element referenced as “top” or “upper” or “above” “bottom,” “lower,” “below,” another element does not have to be with respect to ground, and vice versa. An element referenced as “top” or “upper” or “above” may be above or below such other referenced element, relative to that example only and the particular illustrated example.

Further, an object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An integrated circuit (IC), comprising:
   a bottom die, comprising:
      a first substrate extending in a first direction;
      a first interconnect structure comprising a first side adjacent to the first substrate and a second side opposite of the first side in a second direction orthogonal to the first direction; and
      a first semiconductor layer adjacent to the second side of the first interconnect structure in the second direction,
         the first semiconductor layer comprising one or more first semiconductor devices; and
   a top die, comprising:
      a second substrate extending in the first direction;
      a second interconnect structure comprising a third side adjacent to the second substrate and a fourth side opposite of the third side in the second direction; and
      a second semiconductor layer adjacent to the fourth side of the second interconnect structure in the second direction,
         the second semiconductor layer comprising one or more radio-frequency (RF) semiconductor devices each configured to emit RF energy,
   the fourth side of the second interconnect structure of the top die coupled to the second side of the first interconnect structure of the bottom die.
2. The IC of clause 1, wherein the one or more first semiconductor devices comprise one or more non-RF semiconductor devices each configured to not emit RF energy.
3. The IC of clause 2, wherein the one or more non-RF semiconductor devices comprise one or more devices comprised from one or more digital devices and one or more analog devices.
4. The IC of any of clauses 1-3, wherein the one or more first semiconductor devices comprise at least one non-RF semiconductor device not configured to emit RF energy and at least one RF semiconductor device configured to emit RF energy.
5. The IC of any of clauses 1-4, wherein the second semiconductor layer further comprises one or more non-RF semiconductor devices not configured to emit RF energy.
6. The IC of any of clauses 1-5, wherein the one or more RF semiconductor devices comprise one or more RF switches.
7. The IC of any of clauses 1-5, wherein the one or more RF semiconductor devices comprise one or more low noise amplifiers (LNAs).
8. The IC of any of clauses 1-7, wherein the second substrate does not comprise a trap rich layer.
9. The IC of any of clauses 1-8, wherein the first substrate does not comprise a trap rich layer.
10. The IC of any of clauses 1-9, wherein the first substrate comprises a silicon-on-insulator (SOI) substrate comprising:
   a first semiconductor substrate; and
   a first buried insulator layer (BIL) adjacent to the first semiconductor substrate in the second direction,
   wherein the first semiconductor layer is adjacent to the first BIL in the second direction.
11. The IC of any of clauses 1-10, wherein the second substrate comprises a silicon-on-insulator (SOI) substrate comprising:
   a second semiconductor substrate; and
   a second insulator layer (BIL) adjacent to the second semiconductor substrate in the second direction,
   wherein the second semiconductor layer is adjacent to the second BIL in the second direction.
12. The IC of any of clauses 1-11, wherein the second substrate comprises one or more second passivation layers each comprising a dielectric material.
13. The IC of any of clauses 1-12, wherein the first substrate comprises a semiconductor substrate comprising a semiconductor material.
14. The IC of any of clauses 1-13, wherein:
   the second interconnect structure comprises an inner, second metallization layer adjacent to the first interconnect structure in the second direction,
      the inner, second metallization layer comprising a plurality of second metal interconnects coupled to the one or more RF semiconductor devices; and
   further comprising a plurality of second vias extending through the second substrate and the inner, second metallization layer in the second direction and each coupled to a second metal interconnect of the plurality of second metal interconnects.
15. The IC of clause 14, further comprising a plurality of external metal interconnects exposed from the second substrate and each coupled to a second via of the plurality of second vias.
16. The IC of clause 14 or 15, wherein:
   the first interconnect structure comprises an inner, first metallization layer adjacent to the second interconnect structure in the second direction,
      the inner, first metallization layer comprising a plurality of first metal interconnects coupled to the one or more first semiconductor devices; and
   each first metal interconnect of the plurality of first metal interconnects coupled to a second metal interconnect of the plurality of second metal interconnects.
17. The IC of any of clauses 1-16, wherein:
   the first interconnect structure comprises an outer, first metallization layer adjacent to the first substrate in the second direction,
      the outer, first metallization layer comprising a plurality of first metal interconnects; and
   the second interconnect structure comprises an outer, second metallization layer adjacent to the second substrate in the second direction,
      the outer, second metallization layer comprising a plurality of second metal interconnects; and
   each first metal interconnect of the plurality of first metal interconnects is coupled to a second metal interconnect of the plurality of second metal interconnects.
18. The IC of any of clauses 1-17 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
19. A method of fabricating an integrated circuit (IC) package, comprising:
   forming a bottom die, comprising:
      providing a first substrate extending in a first direction;
      forming a first semiconductor layer adjacent to the first substrate in a second direction orthogonal to the first direction, the first semiconductor layer comprising one or more first semiconductor devices; and
      forming a first interconnect structure adjacent to the first semiconductor layer in the second direction, such that a first side of the first interconnect structure is adjacent to the first semiconductor layer, the first side opposite a second side of the first interconnect structure in the second direction;
   forming a top die, comprising:
      providing a second substrate extending in the first direction;
      forming a second semiconductor layer adjacent to the second substrate in the second direction, the second semiconductor layer comprising one or more radio-frequency (RF) semiconductor devices each configured to emit RF energy; and
      forming a second interconnect structure adjacent to the second semiconductor layer in the second direction, such that a third side of the second interconnect structure is adjacent to the second semiconductor layer, the third side opposite a fourth side of the second interconnect structure in the second direction; and
   coupling the fourth side of the second interconnect structure of the top die to the second side of the first interconnect structure of the bottom die.
20. The method of clause 19, further comprising not forming a trap rich layer in the second substrate.
21. The method of clause 19 or 20, wherein:
   forming the first interconnect structure comprises:
      forming an outer, first metallization layer adjacent to the first substrate in the second direction; and
      forming a plurality of first metal interconnects in the outer, first metallization layer; and
   forming the second interconnect structure comprises:
      forming an outer, second metallization layer adjacent to the second substrate in the second direction,
      forming a plurality of second metal interconnects in the outer, second metallization layer; and
   further comprising coupling each first metal interconnect of the plurality of first metal interconnects to a second metal interconnect of the plurality of second metal interconnects.
22. The method of clause 21, wherein coupling each first metal interconnect of the plurality of first metal interconnects to the second metal interconnect of the plurality of second metal interconnects comprises:
   directly bonding each first metal interconnect of the plurality of first metal interconnects to the second metal interconnect of the plurality of second metal interconnects.
23. The method of any of clauses 19-22, wherein:
   forming the bottom die comprises:
      providing a bottom semiconductor wafer comprising the first substrate extending in the first direction;
      forming the first semiconductor layer adjacent to the first substrate in the second direction orthogonal to the first direction, the first semiconductor layer comprising the one or more first semiconductor devices; and
      forming the first interconnect structure adjacent to the first semiconductor layer in the second direction, such that the first side of the first interconnect structure is adjacent to the first semiconductor layer, the first side opposite the second side of the first interconnect structure in the second direction;
   forming the top die comprises:
      providing a top semiconductor wafer comprising the second substrate comprising a second semiconductor substrate extending in the first direction;
      forming the second semiconductor layer adjacent to the second substrate in the second direction, the second semiconductor layer comprising the one or more RF semiconductor devices each configured to emit RF energy; and
      forming the second interconnect structure adjacent to the second semiconductor layer in the second direction, such that the third side of the second interconnect structure is adjacent to the second semiconductor layer, the third side opposite the fourth side of the second interconnect structure in the second direction; and
   coupling the fourth side of the second interconnect structure of the top die to the second side of the first interconnect structure of the bottom die comprises:
      coupling the fourth side of the second interconnect structure of the top die to the second side of the first interconnect structure of the bottom die to form a combined semiconductor wafer comprising the top semiconductor wafer coupled to the bottom semiconductor wafer.
24. The method of clause 23, further comprising dicing the combined semiconductor wafer into the IC comprising the top die coupled to the bottom die.
25. The method of clause 23 or 24, further comprising:
   removing the second semiconductor substrate from the second semiconductor layer; and
   disposing one or more passivation layers comprising a dielectric material on the second semiconductor layer.

What is claimed is:

1. An integrated circuit (IC), comprising:
a bottom die, comprising:
a first substrate extending in a first direction;
a first interconnect structure comprising a first side adjacent to the first substrate and a second side opposite of the first side in a second direction orthogonal to the first direction; and
a first semiconductor layer adjacent to the second side of the first interconnect structure in the second direction,
the first semiconductor layer comprising one or more first semiconductor devices; and
a top die, comprising:
a second substrate extending in the first direction;
a second interconnect structure comprising a third side adjacent to the second substrate and a fourth side opposite of the third side in the second direction; and
a second semiconductor layer adjacent to the fourth side of the second interconnect structure in the second direction,
the second semiconductor layer comprising one or more radio-frequency (RF) semiconductor devices each configured to emit RF energy,
the fourth side of the second interconnect structure of the top die coupled to the second side of the first interconnect structure of the bottom die.

2. The IC of claim 1, wherein the one or more first semiconductor devices comprise one or more non-RF semiconductor devices each configured to not emit RF energy.

3. The IC of claim 2, wherein the one or more non-RF semiconductor devices comprise one or more devices comprised from one or more digital devices and one or more analog devices.

4. The IC of claim 1, wherein the one or more first semiconductor devices comprise at least one non-RF semiconductor device not configured to emit RF energy and at least one RF semiconductor device configured to emit RF energy.

5. The IC of claim 1, wherein the second semiconductor layer further comprises one or more non-RF semiconductor devices not configured to emit RF energy.

6. The IC of claim 1, wherein the one or more RF semiconductor devices comprise one or more RF switches.

7. The IC of claim 1, wherein the one or more RF semiconductor devices comprise one or more low noise amplifiers (LNAs).

8. The IC of claim 1, wherein the second substrate does not comprise a trap rich layer.

9. The IC of claim 1, wherein the first substrate does not comprise a trap rich layer.

10. The IC of claim 1, wherein the first substrate comprises a silicon-on-insulator (SOI) substrate comprising:
a first semiconductor substrate; and
a first buried insulator layer (BIL) adjacent to the first semiconductor substrate in the second direction,
wherein the first semiconductor layer is adjacent to the first BIL in the second direction.

11. The IC of claim 1, wherein the second substrate comprises a silicon-on-insulator (SOI) substrate comprising:
a second semiconductor substrate; and
a second insulator layer (BIL) adjacent to the second semiconductor substrate in the second direction,
wherein the second semiconductor layer is adjacent to the second BIL in the second direction.

12. The IC of claim 1, wherein the second substrate comprises one or more second passivation layers each comprising a dielectric material.

13. The IC of claim 1, wherein the first substrate comprises a semiconductor substrate comprising a semiconductor material.

14. The IC of claim 1, wherein:
the second interconnect structure comprises an inner, second metallization layer adjacent to the first interconnect structure in the second direction,
the inner, second metallization layer comprising a plurality of second metal interconnects coupled to the one or more RF semiconductor devices; and
further comprising a plurality of second vias extending through the second substrate and the inner, second metallization layer in the second direction and each coupled to a second metal interconnect of the plurality of second metal interconnects.

15. The IC of claim 14, further comprising a plurality of external metal interconnects exposed from the second substrate and each coupled to a second via of the plurality of second vias.

16. The IC of claim 14, wherein:
the first interconnect structure comprises an inner, first metallization layer adjacent to the second interconnect structure in the second direction,
the inner, first metallization layer comprising a plurality of first metal interconnects coupled to the one or more first semiconductor devices; and
each first metal interconnect of the plurality of first metal interconnects coupled to a second metal interconnect of the plurality of second metal interconnects.

17. The IC of claim 1, wherein:
the first interconnect structure comprises an outer, first metallization layer adjacent to the first substrate in the second direction,
the outer, first metallization layer comprising a plurality of first metal interconnects; and
the second interconnect structure comprises an outer, second metallization layer adjacent to the second substrate in the second direction,
the outer, second metallization layer comprising a plurality of second metal interconnects; and
each first metal interconnect of the plurality of first metal interconnects is coupled to a second metal interconnect of the plurality of second metal interconnects.

18. The IC of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

19. A method of fabricating an integrated circuit (IC) package, comprising:
forming a bottom die, comprising:
providing a first substrate extending in a first direction;
forming a first semiconductor layer adjacent to the first substrate in a second direction orthogonal to the first direction, the first semiconductor layer comprising one or more first semiconductor devices; and
forming a first interconnect structure adjacent to the first semiconductor layer in the second direction, such that a first side of the first interconnect structure is adjacent to the first semiconductor layer, the first side opposite a second side of the first interconnect structure in the second direction;
forming a top die, comprising:
providing a second substrate extending in the first direction;
forming a second semiconductor layer adjacent to the second substrate in the second direction, the second semiconductor layer comprising one or more radio-frequency (RF) semiconductor devices each configured to emit RF energy; and
forming a second interconnect structure adjacent to the second semiconductor layer in the second direction, such that a third side of the second interconnect structure is adjacent to the second semiconductor layer, the third side opposite a fourth side of the second interconnect structure in the second direction; and
coupling the fourth side of the second interconnect structure of the top die to the second side of the first interconnect structure of the bottom die.

20. The method of claim 19, further comprising not forming a trap rich layer in the second substrate.

21. The method of claim 19, wherein:
forming the first interconnect structure comprises:
forming an outer, first metallization layer adjacent to the first substrate in the second direction; and
forming a plurality of first metal interconnects in the outer, first metallization layer; and
forming the second interconnect structure comprises:
forming an outer, second metallization layer adjacent to the second substrate in the second direction,
forming a plurality of second metal interconnects in the outer, second metallization layer; and
further comprising coupling each first metal interconnect of the plurality of first metal interconnects to a second metal interconnect of the plurality of second metal interconnects.

22. The method of claim 21, wherein coupling each first metal interconnect of the plurality of first metal interconnects to the second metal interconnect of the plurality of second metal interconnects comprises:
directly bonding each first metal interconnect of the plurality of first metal interconnects to the second metal interconnect of the plurality of second metal interconnects.

23. The method of claim 19, wherein:
forming the bottom die comprises:
providing a bottom semiconductor wafer comprising the first substrate extending in the first direction;
forming the first semiconductor layer adjacent to the first substrate in the second direction orthogonal to the first direction, the first semiconductor layer comprising the one or more first semiconductor devices; and
forming the first interconnect structure adjacent to the first semiconductor layer in the second direction, such that the first side of the first interconnect structure is adjacent to the first semiconductor layer, the first side opposite the second side of the first interconnect structure in the second direction;
forming the top die comprises:
providing a top semiconductor wafer comprising the second substrate comprising a second semiconductor substrate extending in the first direction;
forming the second semiconductor layer adjacent to the second substrate in the second direction, the second semiconductor layer comprising the one or more RF semiconductor devices each configured to emit RF energy; and
forming the second interconnect structure adjacent to the second semiconductor layer in the second direction, such that the third side of the second interconnect structure is adjacent to the second semiconductor layer, the third side opposite the fourth side of the second interconnect structure in the second direction; and
coupling the fourth side of the second interconnect structure of the top die to the second side of the first interconnect structure of the bottom die comprises:
coupling the fourth side of the second interconnect structure of the top die to the second side of the first interconnect structure of the bottom die to form a combined semiconductor wafer comprising the top semiconductor wafer coupled to the bottom semiconductor wafer.

24. The method of claim 23, further comprising dicing the combined semiconductor wafer into the IC comprising the top die coupled to the bottom die.

25. The method of claim 23, further comprising:
removing the second semiconductor substrate from the second semiconductor layer; and
disposing one or more passivation layers comprising a dielectric material on the second semiconductor layer.
